(19) United States
(12) Patent Application Publication
(10) Pub. No.: US 2026/0114158 A1
(43) Pub. Date: Apr. 23, 2026

(54) DISPLAY PANEL AND PREPARATION METHOD THEREFOR

(71) Applicant: KunShan Go-Visionox Opto-Electronics Co., Ltd., Kunshan (CN)

(72) Inventors: Junhui LOU, Langfang (CN); Rubo XING, Langfang (CN); Lingxiao DU, Langfang (CN); Meng ZHANG, Langfang (CN)

(73) Assignee: KunShan Go-Visionox Opto-Electronics Co., Ltd., Kunshan (CN)

(21) Appl. No.: 19/412,710

(22) Filed: Dec. 8, 2025

Related U.S. Application Data
(63) Continuation of application No. PCT/CN2025/098430, filed on May 30, 2025.

(30) Foreign Application Priority Data
Jun. 13, 2024 (CN) 202410763834.1
Aug. 9, 2024 (CN) 202411089934.7

(51) Int. Cl. H10K 59/80; H10K 59/12

(52) U.S. Cl. CPC H10K 59/873; H10K 59/1201; H10K 59/878

(57) ABSTRACT

The present application relates to a display panel, a preparation method therefor, and a display device. The display panel includes: a substrate; a plurality of light-emitting portions spaced apart on one side of the substrate; an insulating structure disposed on a side of the substrate close to the light-emitting portion, the insulating structure defining a plurality of first openings disposed corresponding to the plurality of light-emitting portions, and a protective structure disposed on the side of the substrate close to the light-emitting portion and overlying a surface of the insulating structure close to the substrate, a surface of the insulating structure close to the first opening and a surface of the insulating structure away from the substrate. The present application facilitates an improvement in the service life and the display effects of the display panel and the display device.

### CROSS-REFERENCE TO RELATED APPLICATIONS

The present application is a continuation of International Application No. PCT/CN2025/098430 filed on May 30, 2025, which claims priority to Chinese Patent Application No. 202410763834.1 filed on Jun. 13, 2024 and entitled “DISPLAY PANEL AND PREPARATION METHOD THEREFOR, AND DISPLAY DEVICE”, and Chinese Patent Application No. 202411089934.7 filed on Aug. 9, 2024 and entitled “DISPLAY PANEL AND PREPARATION METHOD THEREFOR, AND DISPLAY DEVICE”, which are incorporated herein by reference in their entireties.

### FIELD

The present application relates to the field of display, and in particular to a display panel and a preparation method therefor.

### BACKGROUND

Organic light-emitting diode (OLED) display panels are widely used due to their many advantages, such as thin thickness, light weight, active luminescence, fast response speed, wide viewing angle, rich colors, high brightness, low power consumption, and resistance to high and low temperatures. Moreover, as people's demands for visual effects continue to increase, display panels are required to offer high-definition display, which means that the display panels are required to have high pixels per inch (PPI). However, the display effects and the service life of current high-PPI display panels need to be further improved.

In addition, in a display panel, a light-emitting structure (e.g., a pixel) is the smallest element that constitutes an image. The display panel is typically provided with multiple light-emitting structures of three basic colors: red, green, and blue. By controlling different light-emitting structures to have different brightness, various colors can be displayed on the display panel.

In the related art, the level of integration of the display panel is usually improved by shortening the distance between adjacent light-emitting structures. However, this makes it easy for light emitted from one light-emitting structure to be emitted from the position of an adjacent light-emitting structure, thereby causing the problem of optical crosstalk.

### SUMMARY

In view of at least one of the above problems, it is necessary to provide a display panel and a preparation method therefor, and a display device, which can improve the display effects and the service life.

In a first aspect, an embodiment of the present application provides a display panel, including:
a substrate;
a plurality of light-emitting portions spaced apart on one side of the substrate;
an insulating structure disposed on a side of the substrate close to the light-emitting portion, the insulating structure defining a plurality of first openings disposed corresponding to the plurality of light-emitting portions, and
a protective structure disposed on the side of the substrate close to the light-emitting portion and overlying a surface of the insulating structure close to the substrate, a surface of the insulating structure close to the first opening and a surface of the insulating structure away from the substrate.

In one embodiment, the protective structure includes:
a first protective layer for overlying the surface of the insulating structure close to the substrate and part of the surface of the insulating structure close to the first opening; and
a second protective layer for overlying the surface of the insulating structure away from the substrate and part of the surface of the insulating structure close to the first opening.

In one embodiment, the first protective layer is connected to the second protective layer.

In one embodiment, the insulating structure includes a first sub-portion and a second sub-portion, the second sub-portion being disposed on a side of the first sub-portion away from the substrate;
an outer contour of an orthographic projection of the second sub-portion on the substrate is located at an outer periphery of an outer contour of an orthographic projection of the first sub-portion on the substrate. In one embodiment, the first protective layer overlies a surface of the first sub-portion close to the substrate and a surface of the first sub-portion close to the first opening.

In one embodiment, the second protective layer overlies a surface of the second sub-portion away from the substrate and a surface of the second sub-portion close to the first opening.

In one embodiment, the second protective layer includes at least one inorganic film layer and at least one metal film layer which are stacked.

In one embodiment, a material of the insulating structure includes an organic material.

In one embodiment, the first protective layer includes:
a first sublayer disposed between the first sub-portion and the substrate; and
a second sublayer disposed on a side of the first sub-portion close to the first opening and connected to the first sublayer.

In one embodiment, the first protective layer further includes a third sublayer, one end of the third sublayer being connected to an end of the second sublayer away from the substrate, and the other end of the third sublayer extending in a direction away from the insulating structure, and protruding from a side wall of the second sub-portion; and the second protective layer is connected to a side of the third sublayer away from the substrate.

In one embodiment, the display panel further includes a plurality of sacrificial structures, where the sacrificial structure is disposed in each of the first openings;
the sacrificial structure is disposed on a side of the light-emitting portion away from the substrate, and the sacrificial structure is provided with a second opening to expose part of the light-emitting portion.

In one embodiment, the protective structure further overlies a surface of the sacrificial structure away from the substrate.

In one embodiment, the sacrificial structure includes a first sacrificial layer and a second sacrificial layer which are stacked in a direction away from the substrate.

In one embodiment, an orthographic projection of the insulating structure on the substrate is in the form of a mesh.

In one embodiment, an orthographic projection of the protective structure on the substrate is in the form of a mesh.

In one embodiment, the display panel further includes:
a plurality of first electrodes spaced apart on the side of the substrate close to the light-emitting portion, the plurality of first electrodes correspond to the plurality of light-emitting portions, and each of the first electrodes being disposed between the corresponding light-emitting portion and the substrate; and
a second electrode disposed on the side of the light-emitting portion away from the substrate, and on a side of the protective structure away from the substrate.

In one embodiment, the display panel further includes a common layer disposed between the second electrode and the plurality of light-emitting portions.

In one embodiment, the display panel further includes a pixel definition layer disposed between the insulating structure and the substrate, the pixel definition layer defining a plurality of third openings, the plurality of first electrodes correspond to the plurality of third openings, and each of the first electrodes being disposed in the corresponding third opening.

In one embodiment, the display panel further includes a reflective layer located on the side of the light-emitting portion away from the substrate, an orthographic projection of the reflective structure on the substrate being at least partially located between orthographic projections of adjacent light-emitting portions on the substrate.

In one embodiment, the reflective layer encloses a plurality of optical openings, an orthographic projection of the first opening on the substrate at least partially overlapping an orthographic projection of the optical opening on the substrate.

In one embodiment, the orthographic projection of the optical opening on the substrate covers the orthographic projection of the first opening on the substrate.

In one embodiment, the reflective layer is located between the protective structure and the insulating structure and covers the surface of the insulating structure away from the substrate.

In one embodiment, the reflective layer covers at least part of a side face of the insulating structure facing the first opening.

In one embodiment, a material of the reflective layer includes metal.

In one embodiment, a material of the protective structure includes a transparent insulating material.

In a second aspect, an embodiment of the present application provides a display panel, including:
a substrate;
a plurality of light-emitting portions spaced apart on one side of the substrate;
an insulating structure disposed on a side of the substrate close to the light-emitting portion, the insulating structure defining a plurality of first openings disposed corresponding to the plurality of light-emitting portions, and a material of the insulating structure including an organic material;
a protective structure for covering a side of the insulating structure away from the substrate, a water absorption of the protective structure being less than a water absorption of the insulating structure; and
a common layer disposed on a side of the protective structure away from the insulating structure.

In a third aspect, an embodiment of the present application provides a method for preparing a display panel, the method including:
providing a substrate;
forming a plurality of spaced-apart light-emitting portions on one side of the substrate; and
forming an insulating structure and a protective structure on a side of the substrate close to the light-emitting portion, where the insulating structure defines a plurality of first openings disposed corresponding to the plurality of light-emitting portions, and the protective structure overlies a surface of the insulating structure close to the substrate, a surface of the insulating structure close to the first opening and a surface of the insulating structure away from the substrate.

In one embodiment, forming an insulating structure and a protective structure on a side of the substrate close to the light-emitting portion includes:
forming a first protective material layer on the side of the substrate close to the light-emitting portion;
forming the insulating structure on a side of the first protective material layer away from the substrate;
forming a second protective material layer on the side of the first protective material layer away from the substrate, where the second protective material layer further covers the insulating structure; and
patterning the first protective material layer and the second protective material layer to form the protective structure.

In one embodiment, the plurality of light-emitting portions includes a plurality of first light-emitting portions, a plurality of second light-emitting portions, and a plurality of third light-emitting portions; and
forming the light-emitting portions on one side of the substrate includes:
forming a plurality of spaced-apart first light-emitting portions on the substrate, and forming a stacked first sacrificial layer and second sacrificial layer on each of the first light-emitting portions;
forming a plurality of spaced-apart second light-emitting portions on the substrate, and
forming a stacked first sacrificial layer and second sacrificial layer on each of the second light-emitting portions; and
forming a plurality of spaced-apart third light-emitting portions on the substrate, and forming a stacked first sacrificial layer and second sacrificial layer on each of the third light-emitting portions.

In one embodiment, patterning the first protective material layer and the second protective material layer to form the protective structure includes:
patterning the second protective material layer to form a second protective layer;
patterning the first protective material layer with the second protective layer as a mask to form a first protective layer;
patterning the second sacrificial layers with the second protective layer as a mask; and patterning the first sacrificial layers with the second protective layer as a mask to form a plurality of sacrificial structures.

In one embodiment, after forming an insulating structure and a protective structure on a side of the substrate close to the light-emitting portion, the method further includes:
forming a common layer on a side of the light-emitting portion away from the substrate; and
forming a second electrode on a side of the common layer away from the substrate.

In one embodiment, before forming a plurality of spaced-apart light-emitting portions on one side of the substrate, the method further includes:
forming a plurality of spaced-apart first electrodes on one side of the substrate.

In one embodiment, the method for preparing a display panel further includes:
forming a plurality of spaced-apart light-emitting portions on one side of the substrate; forming a reflective layer on the side of the light-emitting portion away from the substrate, an orthographic projection of the reflective layer on the substrate being at least partially located between orthographic projections of adjacent light-emitting portions on the substrate; and
forming, on the side of the light-emitting portion away from the substrate, a second electrode for covering the plurality of light-emitting portions.

In a fourth aspect, an embodiment of the present application provides a display device, including the display panel according to any one of the embodiments of the first aspect and the second aspect.

In the display panel and the preparation method therefor, and the display device according to the embodiments of the present application, by providing the protective structure and having the protective structure overlie the surface of the insulating structure close to the substrate, the surface of the insulating structure close to the first opening and the surface of the insulating structure away from the substrate, the protective structure can block moisture in the insulating structure, to protect the light-emitting portion, thereby preventing the light-emitting portion from being corroded by moisture, and thus facilitating an improvement in the service life and the display effects of the display panel and the display device.

In a fifth aspect, an embodiment of the present application provides a display panel, including:
a substrate; a plurality of light-emitting portions spaced apart on one side of the substrate;
a second electrode located on a side of the light-emitting portion away from the substrate; and
an optical structure located on the side of the light-emitting portion away from the substrate, an orthographic projection of the optical structure on the substrate being at least partially located between orthographic projections of adjacent light-emitting portions on the substrate.

In one embodiment, the display panel further includes:
a spacer structure (e.g., an insulating structure) located on the side of the light-emitting portion away from the substrate and enclosing a plurality of first openings, the first opening exposing at least part of the light-emitting portion, and the optical structure being located on a side of the spacer structure away from the substrate.

In one embodiment, the optical structure encloses a plurality of optical openings, an orthographic projection of the first opening on the substrate at least partially overlapping an orthographic projection of the optical opening on the substrate.

In one embodiment, the orthographic projection of the optical opening on the substrate covers the orthographic projection of the first opening on the substrate.

In one embodiment, the optical structure covers at least part of a side face of the spacer structure facing the first opening.

In one embodiment, the spacer structure includes a first sub-portion and a second sub-portion, the second sub-portion being located on a side of the first sub-portion away from the substrate, and the optical structure covering a side face of the second sub-portion facing the first opening.

In one embodiment, an orthographic projection of the second sub-portion on the substrate covers an orthographic projection of the first sub-portion on the substrate.

In one embodiment, the second sub-portion has a top face away from the substrate, the optical structure further covers the top face of the second sub-portion, the optical structure has a top face facing away from the substrate and a side face facing the optical opening, and the second electrode covers the top face of the optical structure and the side face of the optical structure and continuously covers the plurality of light-emitting portions.

In one embodiment, the optical structure covers a top face of the spacer structure away from the substrate.

In one embodiment, the spacer structure includes a first sub-portion and a second sub-portion, the second sub-portion being located on a side of the first sub-portion away from the substrate, and the second sub-portion enclosing an opening formed in communication with the optical opening and exposing the light-emitting portion.

In one embodiment, an orthographic projection of the second sub-portion on the substrate covers an orthographic projection of the first sub-portion on the substrate.

In one embodiment, the optical structure has a top face away from the substrate and a side face facing the optical opening, the second electrode continuously covers the plurality of light-emitting portions and extends along a side face of the second sub-portion of the spacer structure facing the first opening to the side face of the optical structure and the top face of the optical structure.

In one embodiment, a longitudinal cross-section of the second sub-portion above adjacent light-emitting portions in a thickness direction of the substrate is in the shape of an isosceles trapezoid.

In one embodiment, the display panel further includes:
a pixel definition layer located on one side of the substrate, the pixel definition layer having a plurality of light-emitting openings, the light-emitting portion being at least partially located in the light-emitting opening, and the spacer structure being located on a side of the pixel definition layer away from the substrate; and
a first electrode located on a side of the light-emitting portion close to the substrate.

In one embodiment, the display panel further includes a plurality of sacrificial structures, the sacrificial structure being located between the light-emitting portion and the optical structure in the thickness direction of the substrate.

In one embodiment, the sacrificial structure includes a first sacrificial layer and a second sacrificial layer which are stacked.

In one embodiment, the display panel further includes a first protective layer for covering a side face of the light-emitting portion away from the light-emitting opening.

In one embodiment, the first protective layer extends along a side face of the sacrificial structure away from the light-emitting opening to a top face of the sacrificial structure away from the substrate side, and the spacer structure is located on a side of the first protective layer away from the substrate.

In one embodiment, the display panel further includes an encapsulation layer for covering the second electrode and the optical structure.

In one embodiment, the optical structure includes a reflective layer and a second protective layer, the second electrode being located on a side of the second protective layer away from the spacer structure, the reflective layer being located on a side of the second protective layer close to the spacer structure, and the second protective layer being located between the second electrode and the reflective layer.

In one embodiment, a material of the reflective layer includes metal.

In one embodiment, a material of the second protective layer includes a transparent insulating material.

In one embodiment, the display panel further includes:
a common layer located between the second electrode and the optical structure in the thickness direction of the substrate, the common layer continuously covering the plurality of light-emitting portions.

In a sixth aspect, an embodiment of the present application provides a method for preparing a display panel, the method including:
providing a substrate;
forming a plurality of spaced-apart light-emitting portions on one side of the substrate;
forming an optical structure on a side of the light-emitting portion away from the substrate, an orthographic projection of the optical structure on the substrate being at least partially located between orthographic projections of adjacent light-emitting portions on the substrate; and
forming, on the side of the light-emitting portion away from the substrate, a second electrode for covering the plurality of light-emitting portions.

In one embodiment, before forming an optical structure on a side of the light-emitting portion away from the substrate, the method includes:
forming a spacer structure (e.g., an insulating structure) on the side of the light-emitting portion away from the substrate, the spacer structure enclosing a plurality of first openings, the first opening exposing at least part of the light-emitting portion;
forming an optical structure on a side of the light-emitting portion away from the substrate includes:
forming the optical structure on a top face and a side wall of the spacer structure, the optical structure enclosing a plurality of optical openings, an orthographic projection of the first opening on the substrate at least partially overlapping an orthographic projection of the optical opening on the substrate;
forming, on the side of the light-emitting portion away from the substrate, a second electrode for covering the plurality of light-emitting portions includes:
forming a second electrode for covering the optical structure and the plurality of light-emitting portions.

In one embodiment, the optical structure includes a reflective layer and a second protective layer, and forming the optical structure on a top face and a side wall of the spacer structure includes:
forming the reflective layer on the top face and the side wall of the spacer structure; and
forming the second protective layer for covering the reflective layer.

In one embodiment, forming a second electrode for covering the optical structure and the plurality of light-emitting portions includes:
forming a common layer for covering the second protective layer and the plurality of light-emitting portions; and
forming a second electrode for covering the common layer.

In one embodiment, the optical structure includes a reflective structure, the reflective layer including a reflective layer.

In one embodiment, an initial sacrificial layer is further formed on the plurality of light-emitting portions while forming the plurality of spaced-apart light-emitting portions on the substrate;
forming the optical structure on a top face and a side wall of the spacer structure includes:
forming an optical material layer on the spacer structure and the initial sacrificial layer; and
sequentially etching the optical material layer and the initial sacrificial layer to expose the plurality of light-emitting portions, the remaining optical material layer forming the optical structure and the remaining initial sacrificial layer forming a plurality of sacrificial structures.

In one embodiment, the initial sacrificial layer includes a first sacrificial material layer close to the light-emitting portion and a second sacrificial material layer away from the light-emitting portion,
and sequentially etching the optical material layer and the initial sacrificial layer to expose the plurality of light-emitting portions includes:
sequentially etching the optical material layer and the second sacrificial material layer with the first sacrificial material layer as an etch stop layer, leaving the optical material layer and the second sacrificial material layer, the remaining optical material layer forming the optical structure, and the remaining second sacrificial material layer forming a second sacrificial layer; and
etching the first sacrificial material layer with the optical structure and the second sacrificial layer as a mask layer to expose the plurality of light-emitting portions, the remaining first sacrificial material layer forming a first sacrificial layer;

In one embodiment, after forming an initial sacrificial layer on the light-emitting portions, the method includes:
forming a first protective material layer for covering the initial sacrificial layer, the light-emitting portions, and the substrate; and
sequentially etching the optical material layer and the initial sacrificial layer to expose the light-emitting portion includes:
sequentially etching the optical material layer, the first protective material layer, and the initial sacrificial layer to expose the light-emitting portion, the remaining first protective material layer forming a first protective layer.

In one embodiment, forming a spacer structure on the side of the light-emitting portion away from the substrate includes:
forming an insulating material layer on the first protective material layer; and
etching the insulating material layer to form the spacer structure, the spacer structure including a first sub-portion and a second sub-portion, the first sub-portion filling an area between adjacent light-emitting portions, and the second sub-portion being located on a side of the first sub-portion away from the substrate.

In one embodiment, a longitudinal cross-section of the second sub-portion of the spacer structure above adjacent light-emitting portions in a thickness direction of the substrate is in the shape of an isosceles trapezoid.

In one embodiment, an initial sacrificial layer is further formed on the light-emitting portions while forming the plurality of spaced-apart light-emitting portions on the substrate; and forming an optical structure on a side of the light-emitting portion away from the substrate includes:
forming an insulating material layer on the initial sacrificial layer and the substrate;
forming the optical material layer for covering the insulating material layer; and
sequentially etching the optical material layer, the insulating material layer, and the initial sacrificial layer to expose the plurality of light-emitting portions, the remaining optical material layer, the remaining insulating material layer and the remaining initial sacrificial layer forming the optical structure, the spacer structure, and the sacrificial structure.

In a seventh aspect, an embodiment of the present application provides a display device, including the display panel according to any one of the embodiments of the fifth aspect.

In an eighth aspect, an embodiment of the present application provides a display panel, including:
a substrate;
a plurality of light-emitting portions spaced apart on one side of the substrate;
an insulating structure disposed on a side of the substrate close to the light-emitting portion, the insulating structure defining a plurality of first openings disposed corresponding to the plurality of light-emitting portions; and
an optical structure located on a side of the light-emitting portion away from the substrate and overlying a surface of the insulating structure away from the substrate.

In one embodiment, the display panel further includes a protective structure disposed on the side of the substrate close to the light-emitting portion and covering at least the surface of the insulating structure away from the substrate.

In the display panel and the preparation method therefor, and the display device according to the embodiments of the present application, by forming an optical structure on the side of the light-emitting portion away from the substrate, the optical structure can change an optical path of wide-angle light emitted by the light-emitting portion, to prevent the wide-angle light from entering the position of an adjacent pixel, thereby avoiding the problem of optical crosstalk, improving the light extraction efficiency of the light-emitting portion, increasing the brightness of the display panel, improving the display quality of the display panel, and increasing the light utilization rate.

### BRIEF DESCRIPTION OF THE DRAWINGS

To describe the embodiments or exemplary embodiments of the present application more clearly, the following briefly describes the accompanying drawings required for describing the embodiments or the exemplary embodiments. Apparently, the accompanying drawings in the following description show merely some embodiments of the present application.

FIG. 1A is a structural schematic cross-sectional view of a display panel according to an embodiment of the present application.

FIG. 1B is a partial enlarged view of FIG. 1A.

FIG. 2 is a structural schematic partial cross-sectional view of an insulating structure and a protective structure of the display panel shown in FIG. 1.

FIG. 3 is a schematic plan view of the insulating structure and a light-emitting portion of the display panel shown in FIG. 1.

FIG. 4 is a schematic flowchart of a method for preparing a display panel according to an embodiment of the present application.

FIG. 5 is a schematic flowchart of step S300 in the preparation method shown in FIG. 4.

FIG. 6 is a schematic flowchart of step S200 in the preparation method shown in FIG. 4.

FIG. 7 is a schematic flowchart of step S340 in the preparation method shown in FIG. 5.

FIGS. 8-12 are structural schematic cross-sectional views of the display panel during the preparation method shown in FIG. 4.

FIG. 13 is a structural schematic view of a display device according to an embodiment of the present application.

FIG. 14 is a schematic view of a light-emitting portion according to an embodiment.

FIG. 15 is a schematic view of an initial sacrificial layer according to an embodiment.

FIG. 16 is a schematic view of an optical material layer according to an embodiment.

FIG. 17 is a schematic view of a photoresist layer according to an embodiment.

FIG. 18 is a schematic view of an optical structure according to an embodiment.

FIG. 19 is a schematic view of a sacrificial structure according to an embodiment.

FIG. 20A is a schematic view of a display panel according to an embodiment.

FIG. 20B is a partial enlarged view of FIG. 20A.

FIG. 21 is a schematic view of an insulating material layer according to an embodiment.

FIG. 22 is a schematic view of a photoresist layer according to another embodiment.

FIG. 23 is a schematic view of a spacer structure according to an embodiment.

FIG. 24 is a schematic view of a sacrificial structure according to another embodiment.

FIG. 25 is a schematic view of a display panel according to another embodiment.

FIG. 26 is a flowchart of a method for preparing a display panel according to an embodiment.

### LIST OF REFERENCE SIGNS

1. Display device; 10. Display panel; 11. Substrate; 121. Light-emitting portion; 121a. First light-emitting portion; 121b. Second light-emitting portion; 121c. Third light-emitting portion; 122. First electrode; 123. Second electrode; 124. Common layer; 13. Insulating structure (spacer structure); 130. Insulating material layer; 13a. First opening; 131. First sub-portion; 132. Second sub-portion; 1321. Top face; 1322. Side face; 14. Protective structure; 141. First protective layer; 1411. First sublayer; 1412. Second sublayer; 1413. Third sublayer; 142. Second protective layer; 140. Optical structure; 143. Reflective layer; 140a. Optical opening; 15. Sacrificial structure; 15a. Second opening; 151. First sacrificial layer; 152. Second sacrificial layer; 16. Pixel definition layer; 16a. Third opening; 21. First protective material layer; 22. Second protective material layer; 23. Photoresist layer; 190. Encapsulation layer; 1500. Initial sacrificial layer; 1510. First sacrificial material layer; 1520. Second sacrificial material layer; 24. Optical material layer.

### DETAILED DESCRIPTION OF THE EMBODIMENTS

For ease of understanding the present application, the present application will be described more comprehensively below with reference to relevant accompanying drawings. Some embodiments of the present application are given in the accompanying drawings. However, the present application may be implemented in many different forms and is not limited to the embodiments described herein. Rather, these embodiments are provided for a more thorough and comprehensive understanding of the content disclosed in the present application.

It will be appreciated that although terms such as “first”, “second”, etc. may be used herein to describe various elements, these terms do not indicate any order, quantity, or importance, but are merely used to distinguish different components. These terms are merely used to distinguish one element from another. For example, without departing from the scope of the present application, a first element may be referred to as a second element, and similarly, a second element may be referred to as a first element. The term “comprise”, “include”, or similar expressions mean that the element or item preceding the term encompasses elements or items listed after the term and their equivalents, without excluding other elements or items.

Unless otherwise defined, all and scientific terms used herein shall have the same meanings as commonly understood in the art to which the present application belongs.

The terms used herein in the description of the present application are merely for the purpose of describing specific embodiments, and are not intended to limit the present application. The term “and/or” used herein includes any and all combinations of one or more of the associated listed items.

In various embodiments, unless expressly stated or limited otherwise, the terms such as “mounting”, “connection”, “connected” and “fixing” should be interpreted broadly, for example, either a fixed or detachable connection, or integration; may be a mechanical connection or an electrical connection; or may be a direct connection or an indirect connection by means of an intermediate medium, and may be communication between the interiors of two elements or the interaction relationship of the two elements, unless otherwise expressly defined. The specific meanings of the above terms in various embodiments can be understood according to specific situations.

It should be understood that when an element or layer is referred to as being “on”, “adjacent to”, or “connected to” another element or layer, it may be directly on, adjacent to, or connected to the other element or layer, or an intervening element or layer may exist. Conversely, when an element is referred to as being “directly on”, “directly adjacent to”, or “directly connected to” another element or layer, there is no intervening element or layer. It should be understood that although the terms first, second, third, etc. may be used to describe various elements, components, areas, layers and/or portions, these elements, components, areas, layers and/or portions should not be limited by these terms. These terms are merely used to distinguish one element, component, area, layer or portion from another. Therefore, a first element, component, area, layer or portion discussed below may be represented as a second element, component, area, layer or portion without departing from the teaching of this embodiment.

Spatial relationship terms “under”, “beneath”, “lower,” “below”, “above”, “upper”, etc., may be used here to describe the relationship of one element or feature to another element or feature shown in the figures. It should be understood that the spatial relationship terms include different orientations of a device in use and operation, in addition to the orientations shown in the figures. For example, when the device in the figures is inverted, the element or feature described as being “beneath” or “below” or “under”another element will be oriented to be “on”the other element or feature.

Therefore, the exemplary terms “beneath” and “under” may include both the upper and lower orientation positions. In addition, the device may further include an additional orientation (e.g., being rotated by 90 degrees or at other orientation), and the spatial descriptors used herein are interpreted accordingly.

As used herein, the singular forms “a/an”, “one”, and “the” may include plural forms as well, unless the context clearly indicates other manners. It should also be understood that the terms “composed of” and/or “including”, when used in the specification, can determine the presence of the features, integers, steps, operations, elements and/or components, but not exclude the presence or addition of one or more other features, integers, steps, operations, elements, components and/or groups. Furthermore, the term “and/or” used herein includes any and all combinations of the relevant listed items.

Embodiments of the specification are described herein with reference to schematic views of ideal embodiments (and intermediate structures) of the specification, and variations in the shape shown due to, for example, manufacturing techniques and/or tolerances may be expected. Therefore, the embodiments of this specification should not be limited to the particular shape of the area shown herein, but include shape deviations due to, for example, manufacturing techniques. The areas shown in the figures are schematic in nature, and their shapes are not intended to illustrate the actual shapes of the areas of a device nor to limit the scope of this embodiment.

Organic light-emitting diode (OLED) display panels are widely used due to their many advantages, such as thin thickness, light weight, active luminescence, fast response speed, wide viewing angle, rich colors, high brightness, low power consumption, and resistance to high and low temperatures. Moreover, As people's demands for visual effects continue to increase, display panels are required to offer high-definition display, which means that the display panels are required to have high pixels per inch (PPI).

In order to improve the PPI of the display panel, related technologies have abandoned FMM and adopted patterning processes to create light-emitting pixels. In such a display panel, an organic planarization layer is provided between adjacent light-emitting pixels, however, moisture in the organic planarization layer is likely to escape and erode the light-emitting pixels, thereby reducing the display effect and the service life of the display panel.

In view of this, in the display panel and the preparation method therefor, and the display device according to the embodiments of the present application, by providing the protective structure and having the protective structure overlie the surface of the insulating structure close to the substrate, the surface of the insulating structure close to the first opening and the surface of the insulating structure away from the substrate, the protective structure can block moisture in the insulating structure, to protect the light-emitting portion, thereby preventing the light-emitting portion from being corroded by moisture, and thus facilitating an improvement in the service life and the display effects of the display panel and the display device. In the embodiments of the present application, the meaning of “insulation”includes at least “electrical insulation”.

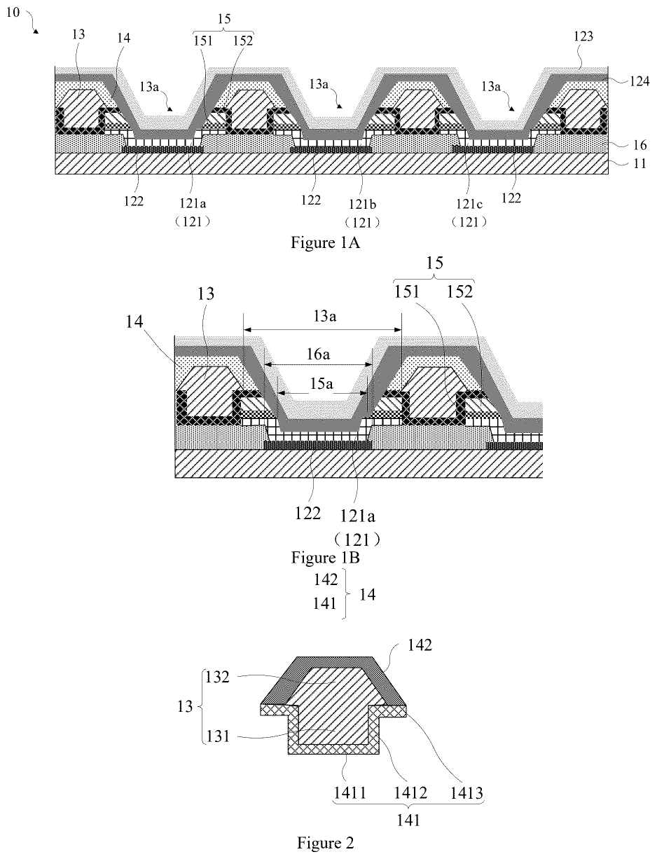

In a first aspect, as shown in FIGS. 1A, 1B and 2, an embodiment of the present application provides a display panel 10. The display panel 10 includes: a substrate 11, a plurality of light-emitting portions 121, an insulating structure 13, and a protective structure 14. The plurality of light-emitting portions 121 are spaced apart on one side of the substrate 11. The insulating structure 13 is disposed on a side of the substrate 11 close to the light-emitting portion 121. The insulating structure 13 defines a plurality of first openings 13adisposed corresponding to the plurality of light-emitting portions 121. The protective structure 14 is disposed on the side of the substrate 11 close to the light-emitting portion 121, and overlies a surface of the insulating structure 13 close to the substrate 11, a surface of the insulating structure 13 close to the first opening 13a, and a surface of the insulating structure 13 away from the substrate 11.

In the embodiment of the present application, the plurality of light-emitting portions 121, the insulating structure 13 and the protective structure 14 are all disposed on the same side of the substrate 11. The insulating structure 13 is disposed between any two adjacent light-emitting portions 121. By providing the insulating structure 13, electrical interference between adjacent light-emitting portions 121 can be reduced. It will be appreciated that the material of the insulating structure 13 may include an organic material, and the insulating structure 13 also has a planarizing function. In this way, the insulating structure 13 can fill a pit between adjacent light-emitting portions 121, thereby facilitating the subsequent process of making a continuous, uniform entire film layer.

In the embodiment of the present application, the surface of the insulating structure 13 close to the substrate 11 may be considered as a bottom surface of the insulating structure 13, and the surface of the insulating structure 13 close to the first opening 13a may be considered as a side surface of the insulating structure 13, and the surface of the insulating structure 13 away from the substrate 11 may be considered as a top surface of the insulating structure 13. By having the protective structure 14 overlie the bottom surface, the side surface, and the top surface of the insulating structure 13, the protective structure 14 can block moisture in the insulating structure 13, to protect the light-emitting portion 121, thereby preventing the light-emitting portion 121 from being corroded by moisture, and thus facilitating an improvement in the service life and the display effect of the light-emitting portion 121.

In one embodiment, referring to FIG. 2, the protective structure 14 includes a first protective layer 141 and a second protective layer 142. The first protective layer 141 overlies the surface of the insulating structure 13 close to the substrate 11 and part of the surface of the insulating structure 13 close to the first opening 13a.

In one embodiment, taking the orientation shown in FIG. 2 as an example, the first protective layer 141 overlies the bottom surface of the insulating structure 13. Further, when the insulating structure 13 is provided with first openings 13a on both left and right sides, the first protective layer 141 also overlies part of the side surface on the left side of the insulating structure 13 and part of the side surface on the right side thereof.

Further, the second protective layer 142 overlies the surface of the insulating structure 13 away from the substrate 11 and part of the surface of the insulating structure 13 close to the first opening 13a. In one embodiment, taking the orientation shown in FIG. 2 as an example, the second protective layer 142 overlies the top surface of the insulating structure 13. Further, when the insulating structure 13 is provided with first openings 13a on both left and right sides, the second protective layer 142 also overlies part of the side surface on the left side of the insulating structure 13 and part of the side surface on the right side thereof.

The above arrangement can enable the protective structure 14 to better overlie the insulating structure 13, to improve the barrier and protective properties of the protective structure 14.

In one embodiment, the first protective layer 141 is connected to the second protective layer 142. In this way, the top surface, the bottom surface, the left side surface and the right side surface of the insulating structure 13 can be completely overlain by the first protective layer 141 and the second protective layer 142, thereby ensuring the barrier and protective properties of the protective structure 14.

In one embodiment, the protective structure 14 may completely cover all outer surfaces of the insulating structure 13, to better block moisture in the insulating structure 13, thereby facilitating an improvement in the service life and the display effect of the light-emitting portion 121.

In one embodiment, the material of the first protective layer 141 may include one or more of silicon nitride, silicon oxide, silicon oxynitride, and aluminum oxide. In this way, it is possible to make the first protective layer 141 better waterproof.

In one embodiment, the material of the second protective layer 142 may be one or more of an inorganic material, a metal material, and a metal oxide material. It should be noted that the second protective layer 142 may be a single film layer or may be a laminated structure. When the second protective layer 142 is a laminated structure, the second protective layer 142 may be a metal laminate, an inorganic laminate, or a metal+organic laminate. By way of example, the inorganic material may be selected from silicon nitride, silicon oxide, silicon oxynitride, and aluminum oxide. The metal material may be selected from titanium, aluminum, molybdenum, etc.

In one embodiment, the second protective layer 142 includes at least one inorganic film layer and at least one metal film layer which are stacked. By way of example, the inorganic film layer may be a silicon nitride layer, a silicon oxide layer, a silicon oxynitride layer, or an aluminum oxide layer, and the metal film layer may be a titanium layer, an aluminum layer or a molybdenum layer. In this way, the protective properties of the second protective layer 142 can be enhanced.

In one embodiment, the material of the insulating structure 13 includes an organic material. In this way, the insulating structure 13 can have a planarizing function, and the insulating structure 13 can fill a pit between adjacent light-emitting portions 121, thereby facilitating the subsequent process of making a continuous, uniform entire film layer.

In one embodiment, referring to FIG. 2, the insulating structure 13 includes a first sub-portion 131 and a second sub-portion 132. The second sub-portion 132 is disposed on a side of the first sub-portion 131 away from the substrate 11, and thus may also be referred to as the “top portion”. An outer contour of an orthographic projection of the second sub-portion 132 on the substrate 11 is located at an outer periphery of an outer contour of an orthographic projection of the first sub-portion 131 on the substrate 11. It should be noted that the first sub-portion 131 may be configured to fill the pit between adjacent light-emitting portions 121, and thus may also be referred to as a “filling portion”.

Still referring to FIG. 2, the above arrangement equivalent to increasing the width of the second sub-portion 132, and during the manufacture of the insulating structure 13, it can be ensured that the insulating material can flow completely into the pit between the adjacent light-emitting portions 121.

Further, as shown in FIG. 2, the thickness of the second sub-portion 132 may gradually increase from an edge of the second sub-portion 132 to the center of the second sub-portion 132. In this way, during the manufacture of a subsequent film layer (e.g., a second electrode 123), it is advantageous for the film layer to climb from the edge of second sub-portion 132 to the top of second sub-portion 132, thereby forming a continuous and relatively uniform film layer.

It will be appreciated that by taking the cross-section shown in FIG. 2 as an example, the cross-sectional shape of the second sub-portion 132 may be a semicircle, a semi-ellipse, an isosceles trapezoid, etc. The cross-sectional shape of the first sub-portion 131 may be a rectangle, an isosceles trapezoid, an inverted trapezoid, etc. The cross-sectional shapes of the first sub-portion 131 and the second sub-portion 132 are not limited in the embodiments of the present application.

In one embodiment, the first protective layer 141 overlies a surface of the first sub-portion 131 close to the substrate 11 and a surface of the first sub-portion 131 close to the first opening 13a. In this way, the first protective layer 141 can overlie the bottom surface and the side surface of the first sub-portion 131, to prevent moisture from escaping from the bottom surface and the side surface of the first sub-portion 131, and thus ensuring the barrier and protective properties of the protective structure 14.

In one embodiment, the second protective layer 142 overlies a surface of the second sub-portion 132 away from the substrate 11 and a surface of the second sub-portion 132 close to the first opening 13a. In this way, the second protective layer 142 can overlie the top surface and the side surface of the second sub-portion 132, to prevent moisture from escaping from the top surface and the side surface of the second sub-portion 132, thereby ensuring the barrier and protective properties of the protective structure 14.

In one embodiment, referring to FIG. 2, the first protective layer 141 includes a first sublayer 1411 and a second sublayer 1412. The first sublayer 1411 is disposed between the first sub-portion 131 and the substrate 11, and the second sublayer 1412 is disposed on the side of the first sub-portion 131 close to the first opening 13a and is connected to the first sublayer 1411. In this way, the bottom surface and the side surface of the first sub-portion 131 can be overlain, to prevent moisture from escaping from the bottom surface and the side surface of the first sub-portion 131, and thus ensuring the barrier and protective properties of the protective structure 14.

In one embodiment, the first protective layer 141 further includes a third sublayer 1413. One end of the third sublayer 1413 is connected to an end of the second sublayer 1412 away from the substrate 11, and the other end of the third sublayer 1413 extends in a direction away from the insulating structure 13, and protrudes from a side wall of the second sub-portion 132. The second protective layer 142 is connected to a side of the third sublayer 1413 away from the substrate 11, that is, the second protective layer 142 is connected in an overlapping manner to the third sublayer 1413. In this way, it is possible to facilitate the overlapping connection between the first protective layer 141 and the second protective layer 142, thereby making the connection properties of the first protective layer 141 and the second protective layer 142 better, to form a more stable, fully-overlain protective structure 14.

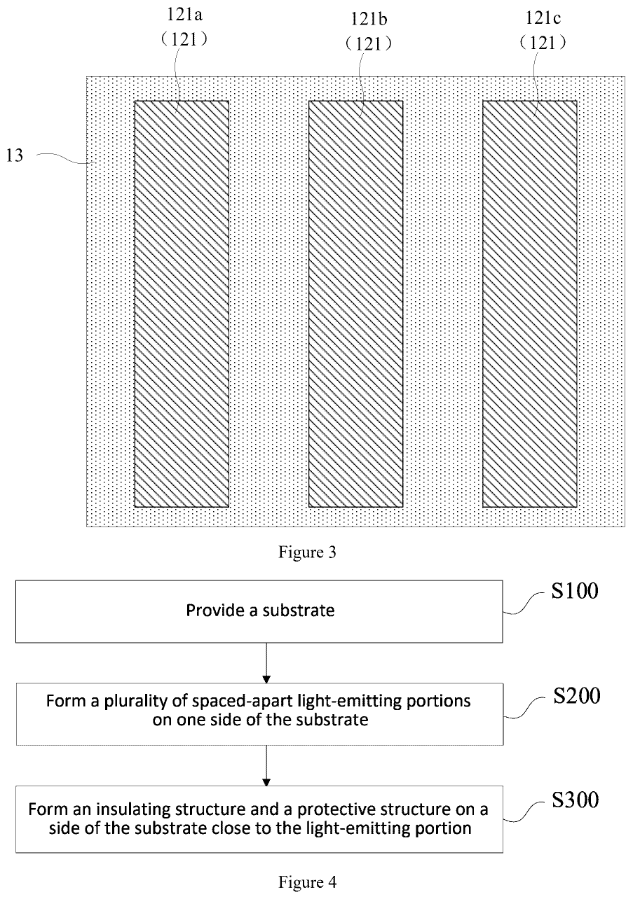

In one embodiment, referring to FIG. 3, an orthographic projection of the insulating structure 13 on the substrate 11 is in the form of a mesh. Mesh openings are the first openings 13a.

Further, an orthographic projection of the protective structure 14 on the substrate 11 is in the form of a mesh.

In one embodiment, referring to FIGS. 1A and 1B, the display panel 10 further includes a plurality of sacrificial structures 15. The sacrificial structure 15 is disposed in each of the first openings 13a. The sacrificial structure 15 is disposed on a side of the light-emitting portion 121 away from the substrate 11, and the sacrificial structure 15 is provided with a plurality of second openings 15a to expose part of the plurality of light-emitting portions 121.

It should be noted that the plurality of sacrificial structures 15 is formed of a sacrificial film layer that remains during the manufacture of the display panel 10. By providing the sacrificial film layer, the plurality of light-emitting portions 121 can be better protected, and an etching solution in the patterning process can be prevented from causing damage to the plurality of light-emitting portions 121. By providing the plurality of sacrificial structures 15, it is advantageous to reduce electrical interference between adjacent light-emitting portions 121.

It will be appreciated that an orthographic projection of each sacrificial structure 15 on the substrate 11 is annular, surrounding the corresponding insulating structure 13.

In one embodiment, the sacrificial structure 15 may include a first sacrificial layer 151 and a second sacrificial layer 152. The first sacrificial layer 151 and the second sacrificial layer 152 may be of different materials. In this way, the light-emitting portion 121 can be better protected, and the etching solution in the patterning process can be prevented from causing damage to the light-emitting portion 121.

It should be noted that the materials of the first sacrificial layer 151 and the second sacrificial layer 152 may be independently selected from silicon nitride, silicon oxide, silicon oxynitride or aluminum oxide.

In one embodiment, the protective structure 14 further overlies a surface of the sacrificial structure 15 away from the substrate 11. In a particular example, the third sublayer 1413 of the first protective layer 141 is disposed on the surface of the sacrificial structure 15 away from the substrate 11.

In one embodiment, the display panel 10 further includes first electrodes 122 and a second electrode 123. A plurality of first electrodes 122 are provided. The plurality of first electrodes 122 are spaced apart on the side of the substrate 11 close to the light-emitting portion 121. The plurality of first electrodes 122 correspond to the plurality of light-emitting portions 121 on a one-to-one basis, and each of the first electrodes 122 is disposed between the corresponding light-emitting portion 121 and the substrate 11. The second electrode 123 is disposed on the side of the light-emitting portion 121 away from the substrate 11, and on a side of the protective structure 14 away from the substrate 11. By way of example, the first electrode 122 may be an anode, and the second electrode 123 may be a cathode. In an embodiment of the present application, the second electrode 123 is a planar electrode, that is, the plurality of light-emitting portions 121 may share the second electrode 123. By providing the second electrode 123 as a planar electrode, it is advantageous to reduce the difficulty of manufacturing the display panel 10.

In one embodiment, the display panel 10 further includes a common layer 124. The common layer 124 is disposed between the second electrode 123 and the plurality of light-emitting portions 121. It should be noted that the common layer 124 may include one film layer or may include a plurality of film layers. In one example, the common layer 124 includes an electron transport layer.

It should be noted that the plurality of light-emitting portions 121 may include a plurality of types of light-emitting portions 121. For example, the plurality of light-emitting portions 121 may include three light-emitting portions 121 for emitting light of different colors, namely, a first light-emitting portion 121a, a second light-emitting portion 121b, and a third light-emitting portion 121c. The different light-emitting portions 121 may include light-emitting film layers of different colors. For example, the first light-emitting portion 121a may include a red light-emitting film layer, the second light-emitting portion 121b may include a green light-emitting film layer, and the third light-emitting portion 121c may include a blue light-emitting film layer. The red light-emitting film layer, the green light-emitting film layer and the blue light-emitting film layer may be arranged on the substrate 11 according to a preset order. Of course, the plurality of light-emitting portions 121 may further include a white light-emitting film layer. A plurality of white light-emitting film layers are arranged in an array on the substrate 11. One light-emitting portion 121 may be one sub-pixel, and a plurality of light-emitting portions 121 may together form a pixel structure. In one embodiment, the first light-emitting portion 121a may include a first light-emitting film layer and a hole transport layer, the second light-emitting portion 121b may include a second light-emitting film layer and a hole transport layer, and the third light-emitting portion 121c may include a third light-emitting film layer and a hole transport layer. In another embodiment, the hole transport layer may also belong to the common layer 124, that is, different light-emitting portions share the same hole transport layer.

In one embodiment, the display panel 10 further includes an optical structure 140, or includes at least a reflective layer 143 in the optical structure 140. The optical structure 140 and its reflective layer 143 are located on the side of the light-emitting portion 121 away from the substrate 11. An orthographic projection of the optical structure 140 and its reflective layer 143 on the substrate 11 is at least partially located between orthographic projections of adjacent light-emitting portions 121 on the substrate 11. Other features of the optical structure 140 and its reflective layer 143 may be described with reference to a sixth aspect.

Referring to FIGS. 1A and 1B, in one embodiment, the display panel 10 further includes a pixel definition layer 16. The pixel definition layer 16 is disposed between the insulating structure 13 and the substrate 11. The pixel definition layer 16 defines a plurality of third openings 16a. The plurality of first electrodes 122 correspond to the plurality of third openings 16a on a one-to-one basis, and each of the first electrodes 122 is disposed in the corresponding third opening 16a.

In one embodiment, the display panel 10 further include an encapsulation layer. The encapsulation layer may cover the second electrode 123, to protect the second electrode 123 and the structure thereunder. The material of the encapsulation layer may include a transparent material.

In a second aspect, referring to FIGS. 1A and 1B, the embodiments of the present application further provide a display panel 10, including a substrate 11, a plurality of light-emitting portions 121, an insulating structure 13, a protective structure 14, and a common layer 124. The plurality of light-emitting portions 121 are spaced apart on one side of the substrate 11. The insulating structure 13 is disposed on a side of the substrate 11 close to the light-emitting portion 121. The insulating structure 13 defines a plurality of first openings 13a disposed corresponding to the plurality of light-emitting portions 121. A material of the insulating structure 13 includes an organic material. The protective structure 14 covers a side of the insulating structure 13 away from the substrate 11. A water absorption of the protective structure 14 is less than that of the insulating structure 13, that is, the moisture content of the insulating structure 13 is greater than the moisture content of the protective structure 14. The common layer 124 is disposed on a side of the protective structure 14 away from the insulating structure 13. By way of example, the common layer 124 may include an electron transport layer, an electron injection layer, etc.

In the display panel 10 according to the embodiments of the present application, by having the protective structure 14 having a smaller moisture content overlie the bottom surface, the side surface and the top surface of the insulating structure 13 having a larger moisture content, the protective structure 14 can block the moisture in the insulating structure 13, to protect the plurality of light-emitting portions 121, thereby preventing the moisture from escaping from the insulating structure 13 to corrode the plurality of light-emitting portions 121, and thus facilitating an improvement in the service life and the display effect of the light-emitting portion 121. Moreover, by providing the common layer 124, it is possible not only to improve the efficiency and the display effect of the display panel 10, but also to avoid providing separate functional layers (such as an electron transport layer and an electron injection layer) for each light-emitting portion 121, thereby facilitating a reduction in the difficulty of preparing the display panel 10. It will be appreciated that the remaining structure of the display panel 10 in the embodiments of the second aspect may be the same as the remaining structure of the display panel 10 in the embodiments of the first aspect, and will not be described again in the embodiments of the present application.

In a third aspect, referring to the flowchart in FIG. 4, and in conjunction with the manufacturing process diagrams of FIGS. 8-12, the embodiments of the present application provide a method for preparing a display panel. The preparation process includes in particular the following steps.

In step S100, a substrate 11 is provided.

In step S200, a plurality of spaced-apart light-emitting portions 121 are formed on one side of the substrate 11. It will be appreciated that the plurality of light-emitting portions 121 may include a plurality of types of light-emitting portions 121. For example, the plurality of light-emitting portions 121 may include three light-emitting portions 121 for emitting different colors, namely, a first light-emitting portion 121a, a second light-emitting portion 121b, and a third light-emitting portion 121c. It will be appreciated that the first light-emitting portion 121a may include a first light-emitting film layer and a hole transport layer, the second light-emitting portion 121b may include a second light-emitting film layer and a hole transport layer, and the third light-emitting portion 121c may include a third light-emitting film layer and a hole transport layer.

In step S300, an insulating structure 13 and a protective structure 14 are formed on a side of the substrate 11 close to the light-emitting portion 121. The insulating structure 13 defines a plurality of first openings 13a disposed corresponding to the plurality of light-emitting portions 121. The protective structure 14 overlies a surface of the insulating structure 13 close to the substrate 11, a surface of the insulating structure 13 close to the first opening 13a, and a surface of the insulating structure 13 away from the substrate 11.

In the method for preparing a display panel according to the embodiments of the present application, by providing the protective structure 14 on the substrate 11 and having the protective structure 14 overlie the surface of the insulating structure 13 close to the substrate 11, the surface of the insulating structure 13 close to the first opening 13a and the surface of the insulating structure 13 away from the substrate 11, the protective structure 14 can block moisture in the insulating structure 13, to protect the plurality of light-emitting portions 121, thereby preventing the plurality of light-emitting portions 121 from being corroded by moisture, and thus facilitating an improvement in the service life and the display effect of the light-emitting portion 121.

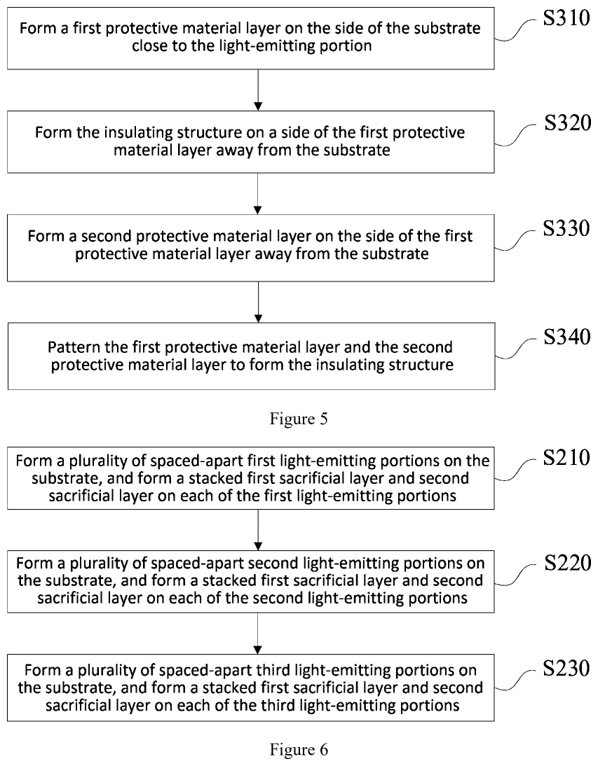

In one embodiment, referring to FIG. 5, step S300 of forming an insulating structure 13 and a protective structure 14 on a side of the substrate 11 close to the light-emitting portion 121 specifically includes the following steps.

In step S310, a first protective material layer 21 is formed on the side of the substrate 11 close to the light-emitting portion 121.

In step S320, the insulating structure 13 is formed on a side of the first protective material layer 21 away from the substrate 11. FIG. 8 is a structural diagram of the first protective material layer 21 and the insulating structure 13 formed.

In step S330, a second protective material layer 22 is formed on the side of the first protective material layer 21 away from the substrate 11. Referring to FIG. 9, after the second protective material layer 22 is formed, the second protective material layer 22 further covers the insulating structure 13.

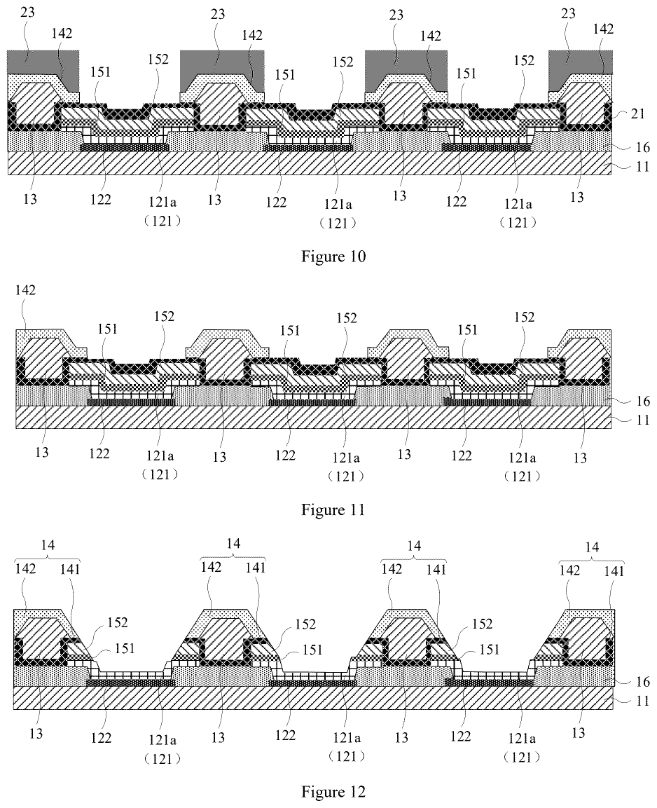

In step S340, the first protective material layer 21 and the second protective material layer 22 are patterned to form the protective structure 14. FIGS. 10 to 12 show the patterning process, and FIG. 14 shows the resulting protective structure 14.

In one embodiment, referring to FIG. 6, step S200 of forming a plurality of spaced-apart light-emitting portions 121 on one side of the substrate 11 specifically includes the following steps.

In step S210, a plurality of spaced-apart first light-emitting portions 121a are formed on the substrate 11, and a stacked first sacrificial layer 151 and second sacrificial layer 152 are formed on each of the first light-emitting portions 121a.

In step S220, a plurality of spaced-apart second light-emitting portions 121b are formed on the substrate 11, and a stacked first sacrificial layer 151 and second sacrificial layer 152 are formed on each of the second light-emitting portions 121b.

In step S230, a plurality of spaced-apart third light-emitting portions 121c are formed on the substrate 11, and a stacked first sacrificial layer 151 and second sacrificial layer 152 are formed on each of the third light-emitting portions 121c.

In one embodiment, step S210 of forming a plurality of spaced-apart first light-emitting portions 121a on the substrate 11, and forming a stacked first sacrificial layer 151 and second sacrificial layer 152 on each of the first light-emitting portions 121a may include the following steps.

In step S211, a first light-emitting material layer, a first sacrificial material layer and a second sacrificial material layer are formed on the substrate 11. The materials of the first sacrificial material layer and the second sacrificial material layer may be metal, an alloy, a metal oxide, a semiconductor, organic matter or inorganic matter.

In step S212, a patterned mask layer is formed on the second sacrificial material layer.

In step S213, the second sacrificial material layer in an exposed area is etched and the second sacrificial layer 152 is formed.

In step S214, the patterned mask layer is removed.

In step S215, the first sacrificial material layer in an exposed area is etched with the second sacrificial layer 152 as a mask to form the first sacrificial layer 151.

It will be appreciated that the specific processes of steps S220 and S230 may be the same as that of step S210, and will not be described again in the embodiments of the present application.

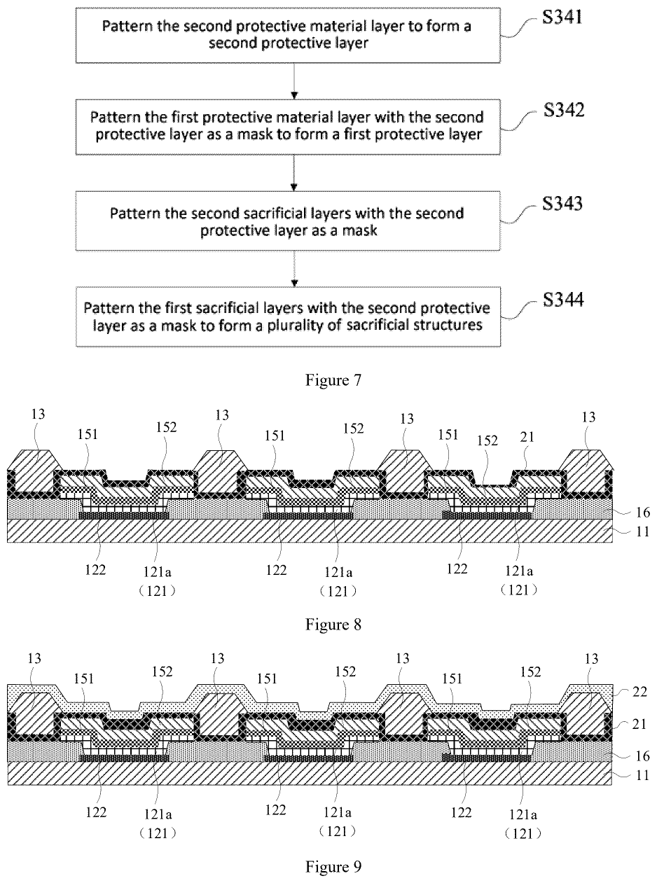

In one embodiment, referring to FIG. 7, step S340 of patterning the first protective material layer 21 and the second protective material layer 22 to form the protective structure 14 specifically includes the following steps.

In step S341, the second protective material layer 22 is patterned to form a second protective layer 142. Specifically, as shown in FIG. 10, a patterned photoresist layer 23 may be formed over the second protective material layer 22, followed by etching the second protective material layer 22. By way of example, a dry etching process or a wet etching process may be employed.

In step S342, the first protective material layer 21 is patterned with the second protective layer 142 as a mask to form a first protective layer 141. In one embodiment, as shown in FIGS. 11 and 12, the photoresist layer 23 is removed and then the first protective material layer 21 is etched with the second protective layer 142 as a mask. By way of example, a dry etching process or a wet etching process may be employed.

In step S343, the second sacrificial layer 152 is patterned with the second protective layer 142 as a mask. In one embodiment, as shown in FIG. 12, the second sacrificial layer 152 is etched with the second protective layer 142 as a mask. By way of example, a dry etching process or a wet etching process may be employed.

In step S344, the first sacrificial layer 151 is patterned with the second protective layer 142 as a mask to form a plurality of sacrificial structures. In one embodiment, as shown in FIG. 12, the first sacrificial layer 151 is etched with the second protective layer 142 as a mask. By way of example, a dry etching process or a wet etching process may be employed.

It should be noted that the second protective layer 142 can prevent the etching solution from causing damage to the plurality of light-emitting portions 121 during the patterning of the first protective material layer 21, the first sacrificial layer 151, and the second sacrificial layer 152.

In one embodiment, after step S300 of forming an insulating structure 13 and a protective structure 14 on a side of the substrate 11 close to the light-emitting portion 121, the method specifically includes the following steps.

In step S400, a common layer 124 is formed on a side of the light-emitting portion 121 away from the substrate 11. By way of example, the common layer 124 may include an electron transport layer.

In step S500, a second electrode 123 is formed on a side of the common layer 124 away from the substrate 11.

In one embodiment, before step S200 of forming a plurality of spaced-apart light-emitting portions 121 on one side of the substrate 11, the method further includes the following step.

In step S150, a plurality of spaced-apart first electrodes 122 are formed on one side of the substrate 11.

It should be noted that in the method for preparing a display panel according to the embodiments of the present application, each film layer may be prepared by a sputtering method, a chemical vapor deposition (CVD) method, a vacuum deposition method, a pulsed laser deposition (PLD) method, an atomic layer deposition (ALD) method, etc. The CVD method includes plasma enhanced chemical vapor deposition (PECVD), laser chemical vapor deposition (LCVD), low pressure chemical vapor deposition (LPCVD), etc.

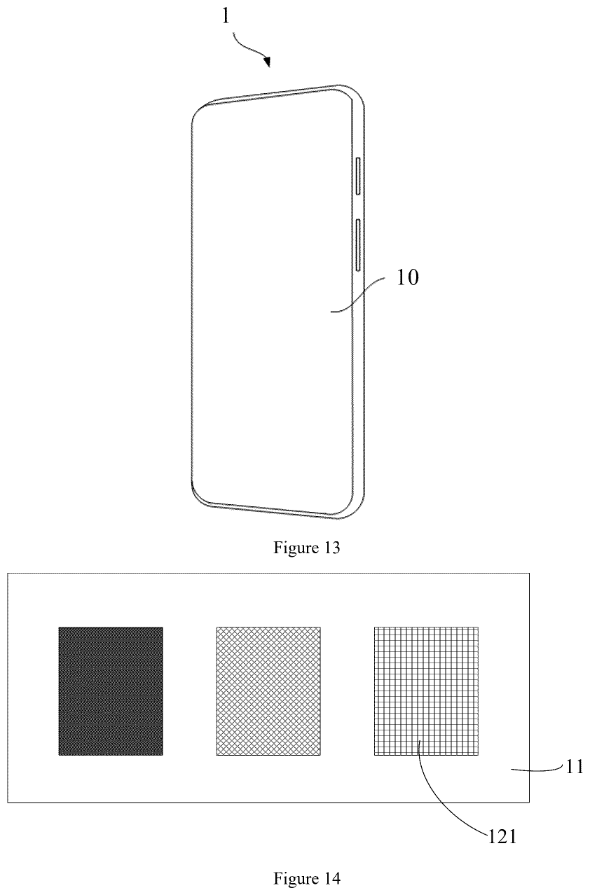

In a fourth aspect, referring to FIG. 13, an embodiment of the present application provides a display device 1, including the display panel 10 according to any one of the embodiments of the first aspect and the second aspect.

The display device 1 may be a notebook computer, a mobile phone, a wireless device, a personal digital assistant (PDA), a handheld or portable computer, a GPS receiver/navigator, a camera, an MP4 video player, a video camera, a game console, a watch, a clock, a calculator, a television monitor, a flat panel display, a computer monitor, a vehicle display (e.g., an odometer display, etc.), a navigation device, a cockpit controller and/or display, a camera view display (e.g., a display for a rearview camera in a vehicle), an electronic photograph, an electronic billboard or signboard, a projector, packaging or the like.

In the display device 1 according to the embodiments of the present application, by providing the protective structure 14 and having the protective structure 14 overlie the surface of the insulating structure 13 close to the substrate 11, the surface of the insulating structure 13 close to the first opening 13a and the surface of the insulating structure 13 away from the substrate 11, the protective structure 14 can block moisture in the insulating structure 13, to protect the plurality of light-emitting portions 121, thereby preventing the plurality of light-emitting portions 121 from being corroded by moisture, and thus facilitating an improvement in the service life and the display effect of the light-emitting portion 121.

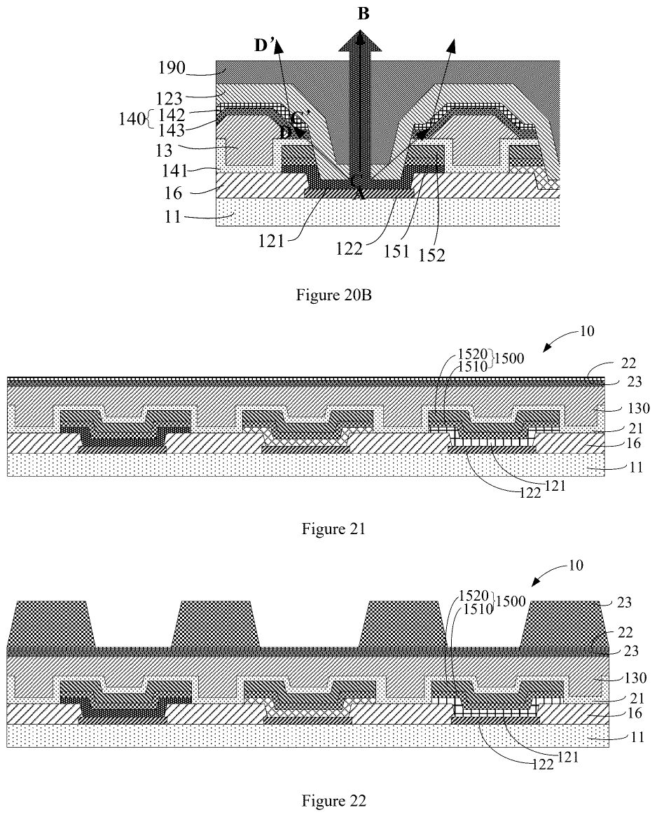

In a fifth aspect, referring to FIGS. 14, 20A and 20B, an embodiment provides a display panel 10, including a substrate 11, a plurality of light-emitting portions 121, a second electrode 123, and an optical structure 140.

The substrate 11 may include an array substrate. The substrate 11 may include a multi-layer film layer. For example, the substrate 11 may include a pixel circuit.

The substrate 11 may include a plurality of light-emitting portions 121. The plurality of light-emitting portions 121 may be spaced apart on one side of the substrate 11. For example, the plurality of light-emitting portions 121 may include a red light-emitting film layer, a green light-emitting film layer, and a blue light-emitting film layer. The red light-emitting film layer, the green light-emitting film layer and the blue light-emitting film layer may be arranged on the substrate 11 according to a preset order. Of course, the plurality of light-emitting portions 121 may further include a white light-emitting film layer. A plurality of white light-emitting film layers are arranged in an array on the substrate 11. In the embodiments of the present application, the “light-emitting portion” may also be referred to as a “light-emitting structure”. The light-emitting portion 121 has a light extraction direction (e.g., a light extraction direction shown by a line segment AB in FIG. 20B). Most of the light emitted by the light-emitting portion 121 can be extracted in the light extraction direction. However, the optical path of a small portion of the light emitted by the light-emitting portion 121 will form a relatively large angle with the light extraction direction, and will be emitted toward the position of an adjacent light-emitting portions 121, which will cause the problem of optical crosstalk. For example, a line segment CD in FIG. 20B shows the optical path of wide-angle light.

The second electrode 123 is located on a side of the light-emitting portion 121 away from the substrate 11. For example, the second electrode 123 may be a cathode.

The second electrode 123 may be connected to a plurality of light-emitting portions 121. For example, the second electrode 123 may continuously cover the plurality of light-emitting portions 121.

Accordingly, the display panel 10 may further include a plurality of first electrodes 122. The first electrode 122 may be an anode. The first electrode 122 may be located on a side of the light-emitting portion 121 close to the substrate 11 and connected to the pixel circuit. It will be appreciated that the first electrode 122 may be provided separately between each light-emitting portion 121 and the substrate 11, and that the plurality of light-emitting portions 121 may share the second electrode 123.

Unless inconsistent with other features of this aspect, the feature descriptions regarding the light-emitting portion 121, the first electrode 122 and the second electrode 123 in the first to fourth aspects are also applicable to the fifth aspect even if not repeated here.

The optical structure 140 is located on the side of the light-emitting portion 121 away from the substrate 11. As an example, the optical structure 140 may include a reflective structure (e.g., a reflective layer 143) capable of reflecting light, an absorbing structure capable of absorbing light, or other prisms or lenses capable of changing the optical path. This embodiment does not specifically limit the composition of the optical structure 140.

An orthographic projection of the optical structure 140 on the substrate 11 is at least partially located between orthographic projections of adjacent light-emitting portions 121 on the substrate 11. As an example, the orthographic projection of the optical structure 140 on the substrate 11 may be entirely located between the orthographic projections of the adjacent light-emitting portions 121 on the substrate 11, or the orthographic projection of the optical structure 140 on the substrate 11 may be located between the orthographic projections of the adjacent light-emitting portions 121 on the substrate 11, and also cover part of the orthographic projection of the light-emitting portion 121 on the substrate 11. It will be appreciated that in a cross-sectional view of display panel 10, the optical structure 140 is located between adjacent light-emitting portions 121. Further, the optical structure 140 may extend in a horizontal direction of the display panel 10. In another possible example, the optical structure 140 may extend in a thickness direction of the display panel 10.

In this embodiment, by forming an optical structure 140 on the side of the light-emitting portion 121 away from the substrate 11, the optical structure 140 can change the optical path of wide-angle light emitted by the light-emitting portion 121, to prevent the wide-angle light from entering the position of an adjacent pixel, thereby avoiding the problem of optical crosstalk, improving the light extraction efficiency of the light-emitting portion 121, increasing the brightness of the display panel 10, improving the display quality of the display panel 10, and increasing the light utilization rate.

In one embodiment, the display panel 10 further includes a spacer structure, such as an insulating structure 13. The spacer structure will be described below by taking the insulating structure 13 as an example, but is not limited to the insulating structure 13. Unless otherwise stated, the insulating structure 13 may be a spacer structure.

The insulating structure 13 is located on the side of the light-emitting portion 121 away from the substrate 11, and the insulating structure 13 encloses a plurality of first openings 13a.

The insulating structure 13 may be formed between adjacent light-emitting portions 121, and the second electrode 123 may be connected to the plurality of light-emitting portions 121. In this case, the insulating structure 13 may have a relatively flat top face and a side wall, thereby facilitating an overlapping connection of the second electrode 123. Unless inconsistent with other features of this aspect, the feature descriptions regarding the insulating structure 13 in the first to fourth aspects are also applicable to the fifth aspect even if not repeated here.

In one possible example, the optical structure 140 is located on a side of the insulating structure 13 away from the substrate 11, and most of the wide-angle light can be prevented from being emitted toward the position of an adjacent light-emitting portions 121. In another possible example, the optical structure 140 is located on a side of the insulating structure 13 close to the substrate 11, and part of the wide-angle light is prevented from being emitted toward the position of an adjacent light-emitting portions 121. In still another possible example, the optical structure 140 may be located both on the side of the insulating structure 13 away from the substrate 11 and on the side of the insulating structure 13 close to the substrate 11.

In this embodiment, first, by providing the insulating structure 13 on the side of the light-emitting portion 121 away from the substrate 11, the overlapping connection of the second electrode 123 is facilitated. Second, in this embodiment, the optical structure 140 is located on a side of the insulating structure 13 away from the substrate 11, and most of the wide-angle light is prevented from being emitted toward the position of an adjacent light-emitting portions 121, thereby avoiding the problem of optical crosstalk.

Referring to FIG. 19, in one embodiment, the optical structure 140 encloses a plurality of optical openings 140a. The optical opening 140a exposes the light-emitting portion 121. An orthographic projection of the first opening 13a on the substrate 11 at least partially overlaps an orthographic projection of the optical opening 140a on the substrate 11. Further, the orthographic projection of the optical opening 140a on the substrate 11 covers the orthographic projection of the first opening 13a on the substrate 11. It will be appreciated that the orthographic projection of the first opening 13a on the substrate 11 may be an orthographic projection on the substrate 11 of a side wall of the insulating structure 13 that encloses the first opening 13a, and the orthographic projection of the optical opening 140a on the substrate 11 may include an orthographic projection on the substrate 11 of a side wall of the optical structure 140 that encloses the optical opening 140a.

By way of example, the optical structure 140 forms a plurality of optical openings 140a. The optical opening 140a exposes at least part of the light-emitting portion 121. The first opening 13a is in communication with the optical opening 140a and jointly exposes the light-emitting portion 121.

In this embodiment, by configuring the optical structure 140 to enclose the plurality of optical openings 140a, the optical structure 140 does not affect the normal light emission of the plurality of light-emitting portions 121.

In one embodiment, the optical structure 140 may include a reflective layer 143 and a second protective layer 142. The reflective layer 143 may be configured to change the optical path of the wide-angle light emitted by the light-emitting portion 121 and the wide-angle light is extracted in the light extraction direction of the light-emitting portion 121, thereby preventing the wide-angle light from entering the position of an adjacent pixel. For example, referring to FIG. 20, the line segment CD shows the optical path of the wide-angle light. The optical path of the wide-angle light is as shown by a line segment C'D' after being reflected by the reflective layer 143. In this case, in one possible example, the material of the reflective layer 143 may be selected to be a material capable of reflecting light. For example, the material of the reflective layer 143 may be a metallic material. For example, the metallic material may be selected from titanium, aluminum, molybdenum, silver, copper or alloys. In another possible example, the reflective layer 143 may include a single-layer film layer, or may include a multi-layer film layer. For example, the reflective layer 143 may be a laminated film layer composed of double titanium layers. In still another possible example, the reflective layer 143 may have a shape capable of reflecting light. For example, the cross-sectional view of the reflective layer 143 may be arch-shaped.

The second protective layer 142 may be located between the second electrode 123 and the reflective layer 143, to isolate the second electrode 123 from the reflective layer 143. It will be appreciated that the embodiment does not limit the specific positional relationship between the reflective layer 143 and the second electrode 123. For example, the reflective layer 143 may be away from the substrate 11 and the second electrode 123 may be close to the substrate 11. In one embodiment, the second electrode 123 may be away from the substrate 11 and the reflective layer 143 may be close to the substrate 11.

The reflective layer 143 may be made of an electrically conductive material. In this case, in one possible example, the material of the second protective layer 142 may include an insulating transparent material such as SiNₓ, SiO₂, SiON, Al₂O₃ or Ta₂O₅, to prevent the second protective layer 142 from reducing the light extraction efficiency of the light-emitting portion 121. For example, the material of the second protective layer 142 may include photosensitive polyimide or acrimic material. Of course, the reflective layer 143 may include a single-layer film layer or may include a multi-layer film layer.

In this embodiment, the second protective layer 142 is disposed between the second electrode 123 and the reflective layer 143, to isolate the second electrode 123 from the reflective layer 143 and prevent the current of the second electrode 123 from being conducted to the reflective layer 143, thereby reducing the possibility of leakage and the possibility of increased power consumption due to leakage. Further, the reflective layer 143 may be connected between adjacent light-emitting portions 121, resulting in lateral leakage, in which case the second protective layer 142 can also reduce the possibility of electrical crosstalk of the light-emitting portions 121 due to lateral leakage.

Further, the second electrode 123 may be located on a side of the second protective layer 142 away from the substrate 11, and the reflective layer 143 may be located on a side of the second protective layer 142 close to the substrate 11. In this case, during the preparation of the display panel 10, the reflective layer 143 may be prepared first, and the second electrode 123 is then prepared over the reflective layer 143, to protect the second electrode 123, thereby avoiding damage to the second electrode 123 due to the preparation of the reflective layer 143. Of course, it is also possible that the second electrode 123 is located on the side of the second protective layer 142 close to the substrate 11, and that the reflective layer 143 is located on the side of the second protective layer 142 away from the substrate 11.

In this embodiment, the optical structure 140 may be located on the side of the insulating structure 13 away from the substrate 11, the second electrode 123 may be located on the side of the second protective layer 142 away from the substrate 11, and the reflective layer 143 may be located on the side of the second protective layer 142 close to the substrate 11, and it is not only possible to prevent most of the wide-angle light from being emitted toward the position of an adjacent light-emitting portions 121, but also to avoid damage to the second electrode 123 due to the preparation of the reflective layer 143.

In one embodiment, the optical structure 140 may cover at least part of a side face of the insulating structure 13 facing the first opening 13a. Of course, the optical structure 140 may further cover the entire side face of the insulating structure 13 facing the first opening 13a.

The insulating structure 13 includes a first sub-portion 131 and a second sub-portion 132. The second sub-portion 132 is located on a side of the first sub-portion 131 away from the substrate 11. By way of example, an orthographic projection of the second sub-portion 132 may cover an orthographic projection of the first sub-portion 131.

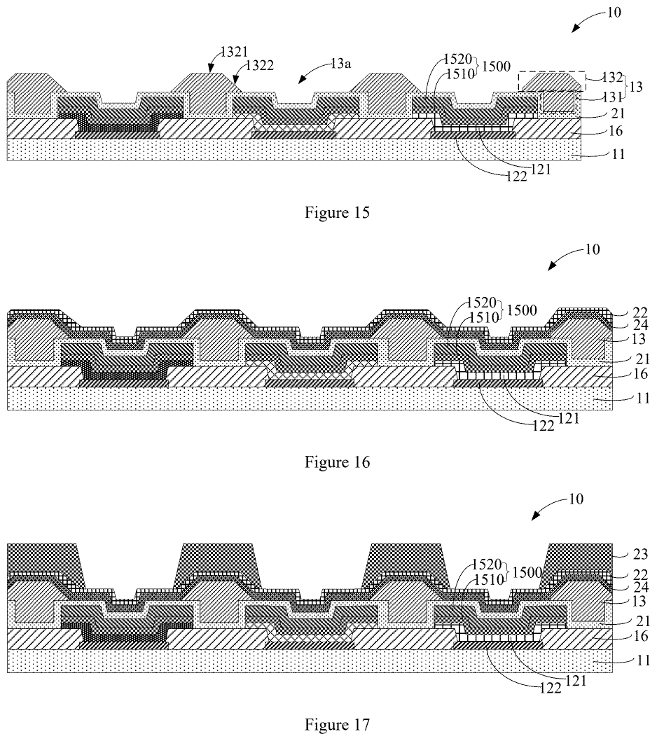

In one possible example, referring to FIG. 15, the second sub-portion 132 of the insulating structure 13 may have a top face 1321 away from the substrate 11 and a side face 1322. The top face 1321 of the second sub-portion 132 may include a horizontal face. For example, the top face 1321 of the second sub-portion 132 may be perpendicular to the light extraction direction. The side face 1322 of the second sub-portion 132 may further include an inclined face. For example, the side face 1322 of the second sub-portion 132 may has an acute angle with the light extraction direction. In this case, the optical structure 140 may cover the side face 1322 of the second sub-portion 132 facing the first opening 13a in order to better reflect the wide-angle light. Of course, the optical structure 140 may also cover the top face 1321 while covering the side face 1322 of the second sub-portion 132 facing the first opening 13a.

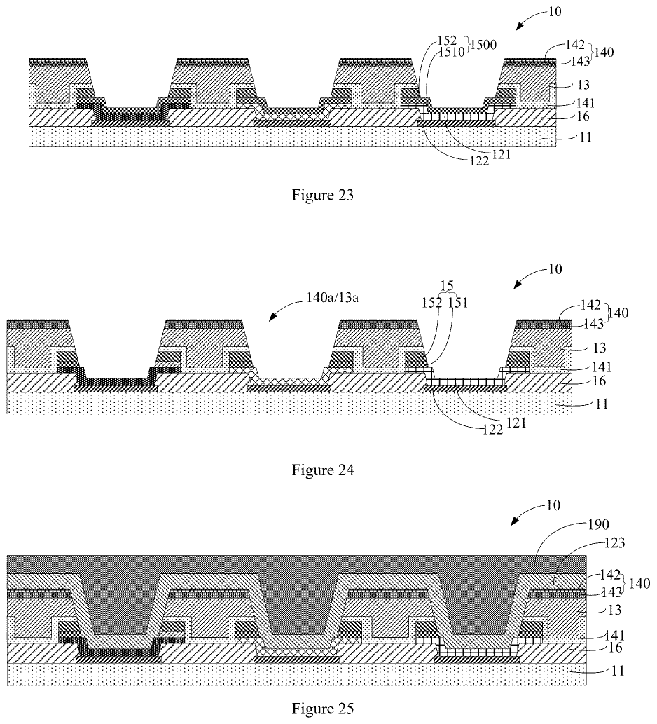

In another possible example, referring to FIG. 23, the second sub-portion 132 of the insulating structure 13 may have a top face 1321 away from the substrate 11. The top face 1321 may include a horizontal face. For example, the top face 1321 of the second sub-portion 132 may be perpendicular to the light extraction direction. An opening enclosed by the second sub-portion 132 may be in communication with the optical opening 140a and expose the light-emitting portion 121. The optical structure 140 may cover the top face 1321, and a side wall of the second sub-portion 132 extends along a side wall of the optical structure 140. In this case, in one possible example, the side wall of the second sub-portion 132 has a first included angle with the light extraction direction, and the side wall of the optical structure 140 has a second included angle with the light extraction direction. The first included angle and the second included angle are equal, and the first included angle and the second included angle are both acute. In another possible example, the orthographic projection of the second sub-portion 132 on the substrate 11 covers the orthographic projection of the first sub-portion 131 on the substrate 11.

In this embodiment, a cover plate or the like may be provided in the light extraction direction of the light-emitting portion 121, and light emitted from the light-emitting portion 121 toward the cover plate may be reflected downwardly by the cover plate (i.e., the cover plate may reflect light toward the substrate 11). When the optical structure 140 covers the top face 1321 of the second sub-portion 132, the optical structure 140 has a top face away from the substrate 11 and a side face facing the optical opening 140a, and the optical structure 140 can re-reflect the light reflected from the cover plate, to increase the light extraction efficiency of the light-emitting portion 121. Moreover, in the above two examples, a longitudinal cross-section of the second sub-portion 132 of the insulating structure 13 above adjacent light-emitting portions 121 in a thickness direction of the substrate 11 may be in the shape of an isosceles trapezoid.

Furthermore, the second electrode 123 may cover the top face of the optical structure 140 away from the substrate 11 and the side face of the optical structure facing the optical opening 140a and continuously cover the plurality of light-emitting portions 121, and the second electrode 123 may continuously cover the plurality of light-emitting portions 121 and extend along the side face of the second sub-portion 132 of the insulating structure 13 facing the first opening 13a to the side face of the optical structure 140 and the top face of the optical structure 140. This facilitates the continuous formation of the second electrode 123.

In one embodiment, referring to FIG. 20A, the display panel 10 further includes any one or more of a pixel definition layer 16, the plurality of sacrificial structures 15, a first protective layer 141, an encapsulation layer 190, a common layer 124, and other structures. Unless inconsistent with other features of this aspect, the feature descriptions regarding the pixel definition layer 16, the plurality of sacrificial structures 15, the first protective layer 141, the encapsulation layer 190, and the common layer 124 in the first to fourth aspects are also applicable to the fifth aspect even if not repeated here.

The pixel definition layer 16 is located on one side of the substrate 11. The pixel definition layer 16 is configured to form the plurality of light-emitting portions 121. The pixel definition layer 16 has a plurality of third openings 16a. The light-emitting portion 121 is at least partially located in the third opening 16a. Furthermore, the light-emitting portion 121 may be located on an upper surface of the third opening 16a. The insulating structure 13 may be located on a side of the pixel definition layer 16 away from the substrate 11.

In the thickness direction of the substrate 11, the sacrificial structure 15 may be located between the light-emitting portion 121 and the optical structure 140. The sacrificial structure 15 may be configured to prepare the light-emitting portion 121. The sacrificial structure 15 includes a first sacrificial layer 151 and a second sacrificial layer 152 which are stacked. Of course, the sacrificial structure 15 may further include a third sacrificial layer, a fourth sacrificial layer, etc.

The first protective layer 141 may be configured to form the insulating structure 13. The first protective layer 141 may cover the substrate 11, the sacrificial structure 15, and a side face of the light-emitting portion 121 away from the light-emitting opening, and the insulating structure 13 may be located on a side of the first protective layer 141 away from the substrate 11 and the sacrificial structure 15. Moreover, the first protective layer 141 may also extend along a side face of the sacrificial structure 15 away from the light-emitting opening to a top face of the sacrificial structure 15 away from the substrate 11. Further, when the optical structure 140 is located on the side of the insulating structure 13 close to the substrate 11, the first protective layer 141 may be shared with the reflective layer 143.

The encapsulation layer 190 may cover the second electrode 123 and the optical structure 140, thereby protecting structures such as the second electrode 123 and the optical structure 140. The material of encapsulation layer 190 may include a transparent material.

In the thickness direction of the substrate 11, the common layer 124 is located between the second electrode 123 and the optical structure 140, and the common layer 124 may continuously cover the plurality of light-emitting portions 121. As an example, the common layer 124 may include an organic functional layer of a light-emitting device such as an electron transport layer, an electron injection layer, a hole transport layer, or a hole injection layer. The present application does not specifically limit the composition of the common layer 124.

In addition, the display panel 10 includes a polarizer or the like. The polarizer may be located on a side of the encapsulation layer 190 away from the substrate 11. The polarizer can be used to reduce reflection and improve the display effect of the display panel 10.

In this embodiment, by providing any one or more of the pixel definition layer 16, the plurality of sacrificial structures 15, the first protective layer 141, the encapsulation layer 190, and other structures in the display panel 10, the display effect of the display panel 10 is enhanced.

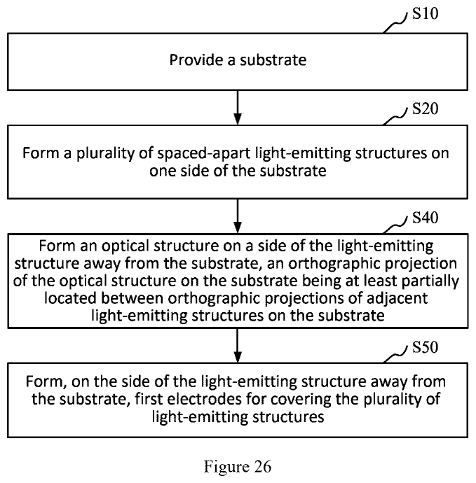

In a sixth aspect, an embodiment of the present application provides a method for preparing a display panel. Referring to FIG. 26, the method for preparing a display panel includes the following steps.

In step S10, a substrate 11 is provided.

In step S20, a plurality of spaced-apart light-emitting portions 121 are formed on one side of the substrate 11.

In step S40, an optical structure 140 is formed on a side of the light-emitting portion 121 away from the substrate 11, an orthographic projection of the optical structure 140 on the substrate 11 being at least partially located between orthographic projections of adjacent light-emitting portions 121 on the substrate 11.

In step S50, a second electrode 123 for covering the plurality of light-emitting portions 121 is formed on the side of the light-emitting portion 121 away from the substrate 11.

In step S10, the substrate 11 may include an encapsulation substrate 11. The substrate 11 may include a multi-layer film layer. For example, the substrate 11 may include a pixel circuit.

In step S20, in one example, the plurality of light-emitting portions 121 may include a red light-emitting film layer, a green light-emitting film layer, and a blue light-emitting film layer. The red light-emitting film layer, the green light-emitting film layer and the blue light-emitting film layer may be arranged on the substrate 11 according to a preset order. In another example, the plurality of light-emitting portions 121 may further include a white light-emitting film layer. A plurality of white light-emitting film layers are arranged in an array on the substrate 11.

A pixel definition layer 16 may be provided on one side of the substrate 11. The pixel definition layer 16 has a plurality of light-emitting openings. In this case, the light-emitting portion 121 may be formed on a bottom face of the light-emitting opening, a side wall, and an upper surface of the light-emitting opening. Of course, the substrate 11 may also be provided with an anode (a first electrode 122), and the light-emitting opening may expose part of the anode.

In step S40, the optical structure 140 may include a reflective structure, an absorbing structure, a prism or a lens, etc. As an example, when the optical structure 140 includes a reflective structure, the optical structure 140 may include a reflective layer 143 and a second protective layer 142. This embodiment does not limit the order in which the reflective layer 143 and the second protective layer 142 are formed. By way of example, one or more of a chemical vapor deposition process, an atomic layer deposition process, a high-density plasma deposition process, a plasma enhanced deposition processes and a spin-on dielectric layer process may be employed to form the reflective layer 143 and the second protective layer 142.

An orthographic projection of the optical structure 140 on the substrate 11 is at least partially located between orthographic projections of adjacent light-emitting portions 121 on the substrate 11. As an example, the orthographic projection of the optical structure 140 on the substrate 11 may be entirely located between the orthographic projections of the adjacent light-emitting portions 121 on the substrate 11, or the orthographic projection of the optical structure 140 on the substrate 11 may be located between the orthographic projections of the adjacent light-emitting portions 121 on the substrate 11, and also cover part of the orthographic projection of the light-emitting portion 121 on the substrate 11. It will be appreciated that in a cross-sectional view of display panel 10, the optical structure 140 is located between adjacent light-emitting portions 121.

In step S50, the second electrode 123 may be a cathode, and the second electrode 123 may continuously cover the plurality of light-emitting portions 121. It will be appreciated that this embodiment does not limit the sequence of step S40 and step S50. That is, in this embodiment, it is possible that the optical structure 140 is formed first and the second electrode 123 is then formed. In this embodiment, it is also possible that the second electrode 123 is formed first and the optical structure 140 is then formed.

In this embodiment, by forming an optical structure 140 on the side of the light-emitting portion 121 away from the substrate 11, the optical structure 140 can change the optical path of wide-angle light, to prevent the wide-angle light from entering the position of an adjacent pixel, thereby avoiding the problem of optical crosstalk, improving the light extraction efficiency of the light-emitting portion 121, increasing the brightness of the display panel 10, and improving the display quality of the display panel 10.

In one embodiment, before step S40, the method includes:
step S30 of forming an insulating structure 13 on the side of the light-emitting portion 121 away from the substrate 11, the insulating structure 13 enclosing a plurality of first openings 13a, the first opening 13a exposing at least part of the light-emitting portion 121.

In this case, step S40 includes:
step S41 of forming the optical structure 140 on a top face and a side wall of the insulating structure 13, the optical structure 140 enclosing a plurality of optical opening 140a, an orthographic projection of the first opening 13a on the substrate 11 at least partially overlapping an orthographic projection of the optical opening 140a on the substrate 11.

Moreover, step S50 includes:
step S51 of forming a second electrode 123 for covering the optical structure 140 and the plurality of light-emitting portions 121.

In step S30, the first opening 13a is in communication with the optical opening 140a and exposes the light-emitting portion 121. In this case, an orthographic projection of the first opening 13a on the substrate 11 at least partially overlaps an orthographic projection of the optical opening 140a on the substrate 11. Further, the orthographic projection of the optical opening 140a on the substrate 11 may cover the orthographic projection of the first opening 13a on the substrate 11.

In one possible example, the optical structure 140 may include a reflective layer 143 and a second protective layer 142. In this case, the reflective layer 143 may be formed first on the top face and the side wall of the insulating structure 13, and the second protective layer 142 for covering the reflective layer 143 is then formed, to form a stacked structure of the insulating structure 13—the reflective layer 143—the second protective layer 142—the second electrode 123. In another possible example, after forming the second protective layer 142, a common layer 124 for covering the second protective layer 142 and the plurality of light-emitting portions 121 may also be formed, and a second electrode 123 for covering the common layer 124 is formed.

By way of example, during the formation of any one of the insulating structure 13, the reflective layer 143, the second protective layer 142, the common layer 124 and the second electrode 123, the film layer may be formed over the entire surface before the film layer is patterned.

In this embodiment, first, the optical structure 140 is located on a side of the insulating structure 13 away from the substrate 11, and most of the wide-angle light can be prevented from being emitted toward the position of an adjacent light-emitting portions 121. Second, in this embodiment, the optical structure 140 is prepared first and the second electrode 123 is then prepared, thereby avoiding damage to the second electrode 123 due to the preparation of the optical structure 140. Thereafter, in this embodiment, the second protective layer 142 is disposed between the second electrode 123 and the reflective layer 143, to isolate the second electrode 123 from the reflective layer 143 and prevent the current of the second electrode 123 from being conducted to the reflective layer 143, thereby reducing the possibility of leakage and the possibility of increased power consumption due to leakage. It is also possible to reduce the possibility of electrical crosstalk of pixels due to lateral leakage.

In one embodiment, referring to FIGS. 15 and 21, simultaneously with step S20, an initial sacrificial layer 1500 is formed on the plurality of light-emitting portions 121. It will be appreciated that the initial sacrificial layer 1500 may be formed on each of the light-emitting portions 121.

In this case, step S41 includes:
step S410 of sequentially forming an optical material layer 24 on the insulating structure 13 and the initial sacrificial layer 1500; and
step S411 of sequentially etching the optical material layer 24 and the initial sacrificial layer 1500 to expose the plurality of light-emitting portions 121, the remaining optical material layer 24 forming the optical structure 140 and the remaining initial sacrificial layer 1500 forming a plurality of sacrificial structure 15.

In step S410 to step S411, referring to FIG. 16, the optical material layer 24 may be formed over the entire surface before the optical material layer 24 and the initial sacrificial layer 1500 are sequentially etched, to form a plurality of optical openings 140a to expose the plurality of light-emitting portions 121. As an example, when etching the optical material layer 24 and the initial sacrificial layer 1500, dry etching or wet etching may be employed. Dry etching may include any one of reactive ion etching, inductively coupled plasma etching, or high-concentration plasma etching. Of course, referring to FIG. 17, a photoresist layer 23 may also be formed over the optical material layer 24 before etching the optical material layer 24 and the initial sacrificial layer 1500, and a plurality of film layers are etched based on the photoresist layer 23.

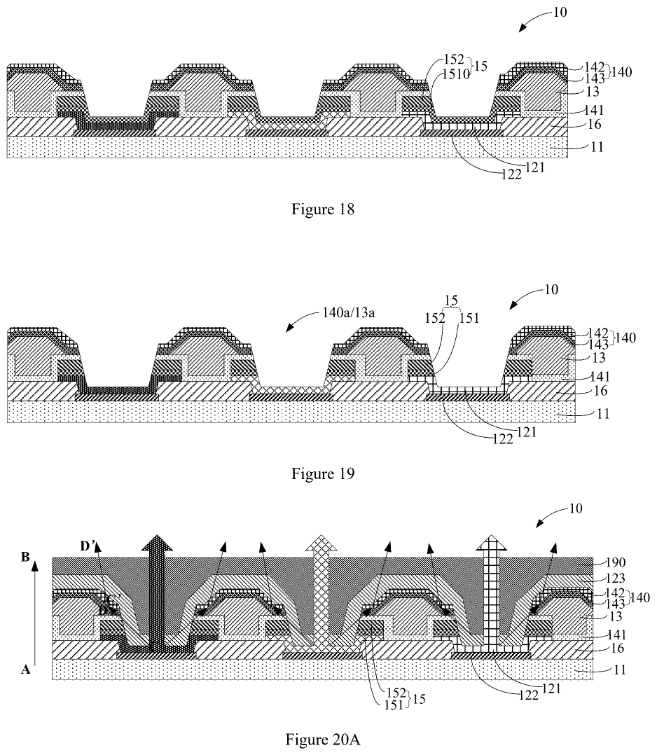

In one possible example, the initial sacrificial layer 1500 includes a first sacrificial material layer 1510 close to the light-emitting portion 121 and a second sacrificial material layer 1520 away from the light-emitting portion 121. In this case, step S411 may be stepwise etching. For example, referring to FIG. 18, the first sacrificial material layer 1510 may be used as an etch stop layer, and the optical material layer 24 and the second sacrificial material layer 1520 may be sequentially etched, leaving the optical material layer 24 and the second sacrificial material layer 1520. The remaining optical material layer 24 forms the optical structure 140, and the remaining second sacrificial material layer 1520 forms the second sacrificial layer 152. Thereafter, referring to FIG. 19, the first sacrificial material layer 1510 is etched with the optical structure 140 and the second sacrificial layer 152 as a mask layer to expose the plurality of light-emitting portions 121. The remaining first sacrificial material layer 1510 forms a first sacrificial layer 151. Of course, the initial sacrificial layer 1500 may further include more film layers. In this example, by configuring the initial sacrificial layer 1500 to include the first sacrificial material layer 1510 and the second sacrificial material layer 1520, the initial sacrificial layer 1500 can be etched stepwise, and the plurality of light-emitting portions 121 can thus be more accurately exposed.

In another possible example, a second protective material layer 22 may be formed on the optical material layer 24. Moreover, the second protective material layer 22 may be etched before etching the optical material layer 24, and the remaining second protective material layer 22 may form the second protective layer 142.

In still another possible example, after forming the initial sacrificial layer 1500 on the plurality of light-emitting portions 121, the method includes:
step S21 of forming a first protective material layer 21 for covering the initial sacrificial layer 1500, the plurality of light-emitting portions 121, and the substrate 11.

In this case, step S30 includes:
step S31 of forming an insulating material layer 130 on the first protective material layer 21; and
step S32 of etching the insulating material layer 130 to form the insulating structure 13, the insulating structure 13 including a first sub-portion 131 and a second sub-portion 132, the first sub-portion 131 filling an area between adjacent light-emitting portions 121, and the second sub-portion 132 being located on a side of the first sub-portion 131 away from the substrate 11.

Accordingly, step S411 includes:
step S4111 of sequentially etching the optical material layer 24, the first protective material layer 21, and the initial sacrificial layer 1500 to expose the plurality of light-emitting portions 121, the remaining first protective material layer 21 forming a first protective layer 141.

In step S21, the first protective material layer 21 may be configured to maintain the etch profile in a subsequent step. The first protective material layer 21 may be formed over the entire surface, to cover the structure of each film layer on the substrate 11.

In steps S31 and S32, the insulating material layer 130 is formed over the entire surface of the first protective material layer 21, and the insulating material layer 130 is then patterned to expose the initial sacrificial layer 1500, to form the insulating structure 13. By way of example, referring to FIG. 15, a longitudinal cross-section of the second sub-portion 132 of the insulating structure 13 above adjacent light-emitting portions 121 is in the shape of an isosceles trapezoid. In this case, the second sub-portion 132 of the insulating structure 13 may have a top face 1321 away from the substrate 11 and a side face 1322. The top face 1321 of the second sub-portion 132 may include a horizontal face. For example, the top face 1321 of the second sub-portion 132 may be perpendicular to the light extraction direction. The side face 1322 of the second sub-portion 132 may further include an inclined face. For example, the side face 1322 of the second sub-portion 132 may has an acute angle with the light extraction direction.

In step S4111, part of the first protective material layer 21 above the plurality of light-emitting portions 121 is removed, and the remaining first protective material layer 21 forms the first protective layer 141.

In this embodiment, by patterning the insulating material layer 130 to form the insulating structure 13, the formation of the inclined side face 1322 of the second sub-portion 132 is facilitated, thereby enabling the formation of an inclined optical structure 140, and thus improving light reflection. Furthermore, the second electrode 123 for covering the second protective layer 142 can be formed subsequently, and the insulating structure 13 enables the second electrode 123 to cover the plurality of light-emitting portions 121 more continuously. Furthermore, the first protective material layer 21 may also facilitate the maintenance of the profile of the film layer during etching, thereby obtaining a more regular optical openings 140a and first openings 13a.

In one embodiment, referring to FIGS. 21 to 24, simultaneously with step S20, an initial sacrificial layer 1500 is formed on the plurality of light-emitting portions 121.

Step S40 includes:
step S420 of forming an insulating material layer 130 on the initial sacrificial layer 1500 and the substrate 11;
step S421 of forming the optical material layer 24 for covering the insulating material layer 130; and
step S422 of sequentially etching the optical material layer 24, the insulating material layer 130, and the initial sacrificial layer 1500 to expose the plurality of light-emitting portions 121, the remaining optical material layer 24, the remaining insulating material layer 130 and the remaining initial sacrificial layer 1500 forming the optical structure 140, the insulating structure 13, and the plurality of sacrificial structures 15.

In steps S420 to S422, the insulating material layer 130 may have a flat upper surface. After the optical material layer 24 is formed, the optical material layer 24 may also be planarized using mechanical grinding, etc., to obtain a flat upper surface. Thereafter, a photoresist layer 23 may be formed on the upper surface of the optical material layer 24, and the optical material layer 24, the insulating material layer 130, and the initial sacrificial layer 1500 are etched in a single etching process based on the photoresist layer 23, to expose the plurality of light-emitting portions 121.

In this embodiment, by forming the optical material layer 24 for covering the insulating material layer 130, the second protective layer 142, the reflective layer 143 and the insulating structure 13 can be obtained in a single etching process, thereby improving the preparation efficiency of the display panel 10 and reducing the number of masks used in the preparation of the display panel 10.

It will be appreciated that although the steps in the flowcharts are displayed in succession as indicated by arrows, these steps are not necessarily performed in succession in the order indicated by the arrows. Unless explicitly described herein, the execution of these steps is not limited to a strict order, instead, the steps may be performed in another order. In addition, at least some of steps in the flowcharts may include a plurality of steps or stages. These steps or stages are not necessarily performed at the same time, but may be performed at different moments. These steps or stages are not necessarily performed in succession, but may be performed in turn or alternately with other steps or at least some of steps or stages in other steps.

In a seventh aspect, an embodiment of the present application provides a display device. The display device includes a display panel formed by a combination of any one or more of the preceding embodiments, or the display device is prepared using a method for preparing a display device provided by any one or more of the preceding embodiments.

In the description of this description, the description with reference to the terms such as “some embodiments”, “other embodiments”, and “ideal embodiments” means that specific features, structures, materials, or characteristics described with respect to the embodiments or examples are included in at least one embodiment or example of the present application. In this description, the schematic descriptions of the above terms do not necessarily refer to the same embodiments or examples. In addition, these particular features, structures, or characteristics may be combined in one or more embodiments in any suitable manner. It will be appreciated that reference throughout the specification to “this embodiment” or “one embodiment” means that a particular feature, structure, or characteristic relating to that embodiment is included in at least one embodiment of the disclosure. Therefore, the expression “in one embodiment” or “in an embodiment” throughout the specification does not necessarily refer to the same embodiment.

When the terms “comprise”, “have”, and “include” are used as described herein, unless otherwise clearly defined, for example, expressions “only” and “composed of.”, another component may further be added. Unless otherwise mentioned, the singular form may include plural forms and should not be construed as the number thereof being one.

The features of the above embodiments may be randomly combined. To make the description concise, not all possible combinations of the features in the above embodiments are described. However, the combinations of these features shall be considered as falling within the scope recorded in the specification provided that no conflict exists.

The above embodiments merely represent several embodiments of the present application, giving specifics and details thereof, but should not be understood as limiting the scope of patent of the present application. It should be noted that several alterations and improvements could be made without departing from the spirit of the present application and these would all fall within the scope of protection of the present application. Therefore, the scope of protection of the present patent application shall be in accordance with the appended claims.

1. A display panel, comprising:
a substrate;
a plurality of light-emitting portions spaced apart on one side of the substrate;
an insulating structure disposed on a side of the substrate close to the light-emitting portion, the insulating structure defining a plurality of first openings disposed corresponding to the plurality of light-emitting portions; and
a protective structure disposed on the side of the substrate close to the light-emitting portion and overlying a surface of the insulating structure close to the substrate, a surface of the insulating structure close to the first opening and a surface of the insulating structure away from the substrate.

2. The display panel according to claim 1, wherein the protective structure comprises: a first protective layer for overlying the surface of the insulating structure close to the substrate and part of the surface of the insulating structure close to the first opening; and a second protective layer for overlying the surface of the insulating structure away from the substrate and part of the surface of the insulating structure close to the first opening.

3. The display panel according to claim 2, wherein the first protective layer is connected to the second protective layer.

4. The display panel according to claim 2, wherein the insulating structure comprises a first sub-portion and a second sub-portion, the second sub-portion being disposed on a side of the first sub-portion away from the substrate;
an outer contour of an orthographic projection of the second sub-portion on the substrate is located at an outer periphery of an outer contour of an orthographic projection of the first sub-portion on the substrate;
the first protective layer overlies a surface of the first sub-portion close to the substrate and a surface of the first sub-portion close to the first opening; and
the second protective layer overlies a surface of the second sub-portion away from the substrate and a surface of the second sub-portion close to the first opening.

5. The display panel according to claim 4, wherein the first protective layer comprises:
a first sublayer disposed between the first sub-portion and the substrate; and
a second sublayer disposed on a side of the first sub-portion close to the first opening and connected to the first sublayer.

6. The display panel according to claim 1, further comprising a plurality of sacrificial structures, wherein the sacrificial structure is disposed in each of the first openings; the sacrificial structure is disposed on a side of the light-emitting portion away from the substrate, and the sacrificial structure is provided with a second opening to expose part of the light-emitting portion.

7. The display panel according to claim 1, wherein an orthographic projection of the insulating structure on the substrate is in the form of a mesh; and
an orthographic projection of the protective structure on the substrate is in the form of a mesh.

8. The display panel according to claim 1, wherein the display panel further comprises:
a plurality of first electrodes spaced apart on the side of the substrate close to the light-emitting portion, the plurality of first electrodes corresponding to the plurality of light-emitting portions, and each of the first electrodes being disposed between the corresponding light-emitting portion and the substrate; and
a second electrode disposed on the side of the light-emitting portion away from the substrate, and on a side of the protective structure away from the substrate.

9. The display panel according to claim 1, further comprising a reflective layer located on the side of the light-emitting portion away from the substrate, wherein an orthographic projection of the reflective layer on the substrate is at least partially located between orthographic projections of adjacent light-emitting portions on the substrate; and the reflective layer is located between the protective structure and the insulating structure and covers the surface of the insulating structure away from the substrate.

10. The display panel according to claim 9, wherein the reflective layer encloses an optical opening, an orthographic projection of the first opening on the substrate at least partially overlapping an orthographic projection of the optical opening on the substrate.

11. The display panel according to claim 10, wherein the orthographic projection of the optical opening on the substrate covers the orthographic projection of the first opening on the substrate.

12. The display panel according to claim 9, wherein the reflective layer covers at least part of a side face of the insulating structure facing the first opening.

13. The display panel according to claim 9, wherein a material of the reflective layer comprises metal.

14. The display panel according to claim 1, wherein a material of the protective structure comprises a transparent insulating material.

15. A method for preparing a display panel, the method comprising:
providing a substrate;
forming a plurality of spaced-apart light-emitting portions on one side of the substrate; and
forming an insulating structure and a protective structure on a side of the substrate close to the light-emitting portion, wherein the insulating structure defines a plurality of first openings disposed corresponding to the plurality of light-emitting portions; and the protective structure overlies a surface of the insulating structure close to the substrate, a surface of the insulating structure close to the first opening and a surface of the insulating structure away from the substrate.

16. The method for preparing a display panel according to claim 15, wherein forming an insulating structure and a protective structure on a side of the substrate close to the light-emitting portion comprises:
forming a first protective material layer on the side of the substrate close to the light-emitting portion;
forming the insulating structure on a side of the first protective material layer away from the substrate;
forming a second protective material layer on the side of the first protective material layer away from the substrate, wherein the second protective material layer further covers the insulating structure; and
patterning the first protective material layer and the second protective material layer to form the protective structure.

17. The method for preparing a display panel according to claim 16, wherein the plurality of light-emitting portions comprises a plurality of first light-emitting portions, a plurality of second light-emitting portions, and a plurality of third light-emitting portions; and
forming a plurality of spaced-apart the light-emitting portions on one side of the substrate comprises:
forming a plurality of spaced-apart first light-emitting portions on the substrate, and forming a stacked first sacrificial layer and second sacrificial layer on each of the first light-emitting portions;
forming a plurality of spaced-apart second light-emitting portions on the substrate, and forming a stacked first sacrificial layer and second sacrificial layer on each of the second light-emitting portions; and
forming a plurality of spaced-apart third light-emitting portions on the substrate, and forming a stacked first sacrificial layer and second sacrificial layer on each of the third light-emitting portions.

18. The method for preparing a display panel according to claim 17, wherein patterning the first protective material layer and the second protective material layer to form the protective structure comprises:
patterning the second protective material layer to form a second protective layer;
patterning the first protective material layer with the second protective layer as a mask to form a first protective layer;
patterning the second sacrificial layers with the second protective layer as a mask; and
patterning the first sacrificial layers with the second protective layer as a mask to form sacrificial structures.

19. The method for preparing a display panel according to claim 15, further comprising:
forming a plurality of spaced-apart light-emitting portions on one side of the substrate;
forming a reflective layer on the side of the light-emitting portion away from the substrate, an orthographic projection of the reflective layer on the substrate being at least partially located between orthographic projections of adjacent light-emitting portions on the substrate; and
forming, on the side of the light-emitting portion away from the substrate, a second electrode for covering the plurality of light-emitting portions.

20. A display panel, comprising:
a substrate;
a plurality of light-emitting portions spaced apart on one side of the substrate;
a second electrode located on a side of the light-emitting portion away from the substrate; and
an optical structure located on the side of the light-emitting portion away from the substrate, an orthographic projection of the optical structure on the substrate being at least partially located between orthographic projections of adjacent light-emitting portions on the substrate.
